(19) United States
(12) Patent Application Publication
(10) Pub. No.: US 2024/0178021 A1
(43) Pub. Date: May 30, 2024

(54) LOAD LOCK ARRANGEMENTS, SEMICONDUCTOR PROCESSING SYSTEMS HAVING LOAD LOCK ARRANGEMENTS, AND METHODS OF MAKING LOAD LOCKS FOR SEMICONDUCTOR PROCESSING SYSTEMS

(71) Applicant: ASM IP Holding B.V., Almere (NL)

(72) Inventors: Senthil Sivaraman, Phoenix, AZ (US); Mandar Deshpande, Phoenix, AZ (US); Samer Banna, Phoenix, AZ (US)

(21) Appl. No.: 18/522,152

(22) Filed: Nov. 28, 2023

Related U.S. Application Data
(60) Provisional application No. 63/385,520, filed on Nov. 30, 2022.

(51) Int. Cl. H01L 21/67; H01L 21/677

(52) U.S. Cl. CPC H01L 21/67201; H01L 21/67098; H01L 21/6719; H01L 21/67742

(57) ABSTRACT

A load lock arrangement includes a load lock body having an upper plate member defining an upper accessory seat, an intermediate plate member spaced apart from the upper plate member and defining an intermediate accessory seat, and a lower plate member separated from the upper plate member by the intermediate plate member and defining a lower accessory seat. One of an upper heater and an upper accessory seat blanking plate is fixed to the upper accessory seat; one of an upper chill plate and an intermediate accessory seat blanking plate fixed to the intermediate accessory seat; and one of a lower chill plate, a lower heater, and a lower accessory seat blanking plate fixed to the lower accessory seat. Semiconductor processing systems, methods of making load lock arrangements, and material layer deposition methods are also described.

### CROSS-REFERENCE TO RELATED APPLICATION(S)

This application claims the benefit of U.S. Provisional Application 63/385,520 filed on Nov. 30, 2022, the entire contents of which are incorporated herein by reference.

### FIELD OF INVENTION

The present disclosure generally relates to fabricating semiconductor devices. More particularly, the present disclosure relates to load lock arrangements for semiconductor processing systems employed to fabricate semiconductor devices.

### BACKGROUND OF THE DISCLOSURE

Semiconductor processing systems, such as semiconductor processing systems with cluster-type platforms, commonly include a front-end connected to a back-end by a load lock. The front-end generally interfaces the semiconductor processing system to the external environment and typically includes a front-end robot to transfer substrates between the front-end of the semiconductor processing system and the load lock. The back-end typically includes a process module wherein substrate processing is accomplished and a back-end robot to transfer substrates between the load lock and the process module. The load lock generally couples the back-end of the semiconductor processing system to the front-end of the semiconductor processing system and is typically arranged to isolate the environment maintained in the back-end of the semiconductor processing system to the environment maintained in the front-end of the semiconductor processing system.

One challenge to load locks is the need to incorporate different types of accessories within the load lock to facilitate substrate processing in the semiconductor processing system. For example, a heating arrangement may be incorporated in the load lock for heating substrates prior to transferring into the process module, improving system throughout by limiting the time required for temperature ramping in the process module. A cooling arrangement may be incorporate into the load lock for cooling substrates prior to transfer from the process module into the load lock, limiting time required to ramp the substrates from the desired material layer deposition temperature subsequent to material layer deposition. This can also improve system throughput by reducing the time that a substrate may remain in the process module subsequent to material layer deposition. Incorporation of substrate heating and substrate cooling in load locks generally requires that the load lock have a customized configuration corresponding to substrate heating and/or substrate cooling requirements of the process performed in the process module coupled to the load lock.

While generally satisfactory insofar that customization enables the load lock to satisfy the requirements of a given processing operation, customization typically adds cost and complexity to the load lock offerings of the load lock manufacturer. For example, customization typically reduces the economies of scale otherwise achievable without customization. Customization may also complicate support of the load lock during service, for example, by increasing number and type of spare parts that be available during the service life of the load lock. And customization can complicate redeployment and/or reuse of semiconductor processing system, for example, by requiring that the load lock be replaced in the event that a process module is converted to perform another processing operation necessitating that the load lock include an accessory not originally included in the load lock.

Such systems and methods have generally been acceptable for their intended purpose. However, there remains a need in the art for improved load lock arrangements, semiconductor processing systems having load lock arrangements, material layer deposition methods, and methods of making load lock arrangements for semiconductor processing systems. The present disclosure provides a solution to this need.

### SUMMARY OF THE DISCLOSURE

A load lock arrangement is provided. The load lock arrangement includes a load lock body having an upper plate member defining an upper accessory seat, an intermediate plate member spaced apart from the upper plate member and defining an intermediate accessory seat, and a lower plate member separated from the upper plate member by the intermediate plate member and defining a lower accessory seat. One of an upper heater and an upper accessory seat blanking plate is fixed to the upper accessory seat; one of an upper chill plate and an intermediate accessory seat blanking plate fixed to the intermediate accessory seat; and one of a lower chill plate, a lower heater, and a lower accessory seat blanking plate fixed to the lower accessory seat.

In addition to one or more of the features described above, or as an alternative, further examples may include that the upper accessory seat blanking plate is fixed to the upper accessory seat, that the intermediate accessory seat blanking plate is fixed to the intermediate accessory seat, and that the lower accessory seat blanking plate is fixed to the lower accessory seat.

In addition to one or more of the features described above, or as an alternative, further examples may include that the upper plate member defines an upper actuator seat and that the load lock arrangement further includes an upper actuator seat blanking plate fixed to the upper actuator seat.

In addition to one or more of the features described above, or as an alternative, further examples may include that the lower plate member defines a lower actuator seat, and that the load lock arrangement further comprises a lower actuator seat blanking plate fixed to the lower actuator seat.

In addition to one or more of the features described above, or as an alternative, further examples may include that the upper heater is fixed to the upper accessory seat, that the lower chill plate is fixed to the lower accessory seat, and that the intermediate accessory seat blanking plate is fixed to the intermediate accessory seat.

In addition to one or more of the features described above, or as an alternative, further examples may include that the upper plate member defines an upper actuator seat and that the load lock arrangement further includes an upper actuator seat blanking plate fixed to the upper actuator seat.

In addition to one or more of the features described above, or as an alternative, further examples may include that the lower plate member defines a lower actuator seat, that the load lock arrangement further includes a lower set plate actuator. The lower set plate actuator may be fixed to the lower set plate actuator seat. The lower set plate actuator may be configured to move a lower set plate between a first lower set plate position and a second lower set plate position relative to the lower plate member.

In addition to one or more of the features described above, or as an alternative, further examples may include that the upper heater is fixed to the upper accessory seat, that the lower heater may fixed to the lower accessory seat, and that the intermediate accessory seat blanking plate may be fixed to the intermediate accessory seat.

In addition to one or more of the features described above, or as an alternative, further examples may include that the upper plate member defines an upper actuator seat and that the load lock arrangement further includes an upper actuator seat blanking plate. The upper actuator seat blanking plate may be fixed to the upper actuator seat.

In addition to one or more of the features described above, or as an alternative, further examples may include that the lower plate member defines a lower actuator seat and that the load lock arrangement further includes a lower actuator seat blanking plate. The lower actuator seat blanking plate may be fixed to the lower actuator seat defined by the lower plate member of the load lock body.

In addition to one or more of the features described above, or as an alternative, further examples may include that the upper chill plate is fixed to the intermediate accessory seat, that the lower chill plate may be fixed to the lower accessory seat, and that the upper accessory seat blanking plate may be fixed to the upper accessory seat.

In addition to one or more of the features described above, or as an alternative, further examples may include that the upper plate member defines an upper actuator seat and that the load lock arrangement further includes an upper set plate actuator. The upper set plate actuator may be fixed to the upper actuator seat. The upper set plate actuator may be configured to move an upper set plate between a first upper set plate position and a second upper set plate position relative to the upper plate member of the load lock body.

In addition to one or more of the features described above, or as an alternative, further examples may include that the lower plate member defines a lower actuator seat and that the load lock arrangement further includes a lower set plate actuator. The lower set plate actuator may be fixed to the lower actuator seat. The lower set plate actuator may be configured to move a lower set plate between a first lower set plate position and a second lower set plate position relative to the lower plate member.

In addition to one or more of the features described above, or as an alternative, further examples may include an evacuation/vent source. The evacuation/vent source may be connected to the load lock body for evacuation/venting or purging an upper chamber and/or a lower chamber defined within the load lock body.

In addition to one or more of the features described above, or as an alternative, further examples may include that the load lock body defines an upper chamber. The upper chamber may be bounded by the upper plate member and the intermediate plate member. The load lock arrangement may include a first upper set plate arranged between the upper accessory seat and the intermediate accessory seat. The load lock arrangement may include a second upper set plate stacked on the first upper set plate and arranged between the first upper set plate and the upper accessory seat defined by the upper plate member of the load lock body.

In addition to one or more of the features described above, or as an alternative, further examples may include that the first upper set plate and the second upper set plate are fixed within the upper chamber relative to the upper plate member.

In addition to one or more of the features described above, or as an alternative, further examples may include that the second upper set plate is fixed relative to the first upper set plate, and wherein the first upper set plate has a first upper set plate position and a second upper set plate position, that the first upper set plate may be proximate the intermediate accessory seat in the first upper set plate position, and that the first upper set plate may be distal from the intermediate accessory seat in the second upper set plate position.

In addition to one or more of the features described above, or as an alternative, further examples may include that load lock body defines a lower chamber bounded by the intermediate plate member and the lower plate member. The load lock arrangement may include a first lower set plate arranged between the intermediate accessory seat and the lower accessory seat. The load lock arrangement may include a second lower set plate stacked on the first lower set plate and arranged between the first lower set plate and the intermediate accessory seat defined by the intermediate plate member of the load lock body.

In addition to one or more of the features described above, or as an alternative, further examples may include that the first lower set plate and the second lower set plate are fixed within the lower chamber defined within the load lock body relative to the upper plate member of the load lock body.

In addition to one or more of the features described above, or as an alternative, further examples may include that the second lower set plate is fixed relative to the first lower set plate and that the first lower set plate has a first lower set plate position and a second lower set plate position. The first lower set plate may be proximate to the lower accessory seat in the first lower set plate position. The first lower set plate may be distal from the lower accessory seat in the second lower set plate position.

A semiconductor processing system is provided. The semiconductor processing system includes a process module, a back-end transfer module connected to the process module and housing a back-end substrate transfer robot, and a load lock arrangement as described above. The load lock arrangement is connected to back-end transfer module and couples the process module to an equipment front-end module to the load lock arrangement housing a front-end substrate transfer robot. The load lock body defines an upper chamber bounded by the upper plate and member and the intermediate plate member, the load lock body defines a lower chamber bounded by the intermediate plate member and the lower plate member, and the front-end substrate transfer robot and the back-end substrate transfer robot are configured to transfer substrates between the equipment front-end module and the process module through the upper chamber and the lower chamber defined within the load lock body.

In addition to one or more of the features described above, or as an alternative, further examples may include that the upper accessory seat blanking plate is fixed to the upper accessory seat, that the intermediate accessory seat blanking plate may be fixed to the intermediate accessory seat, and that the lower accessory seat blanking plate may be fixed to the lower accessory seat. The load lock arrangement may further include a first upper set plate arranged between the upper accessory seat and the intermediate accessory seat, the first upper set plate fixed relative to the load lock body; and a second upper set plate stacked on the first upper set plate, arranged between the first upper set plate and the upper accessory seat, and fixed relative to the first upper set plate.

In addition to one or more of the features described above, or as an alternative, further examples may include that the upper heater is fixed to the upper accessory seat, that the lower chill plate may be fixed to the lower accessory seat, and that the intermediate accessory seat blanking plate may be fixed to the intermediate accessory seat. The load lock arrangement may further include a first upper set plate arranged between the upper accessory seat and the intermediate accessory seat, the first upper set plate fixed relative to the load lock body; and a first lower set plate arranged between the lower accessory seat and the intermediate accessory seat, the first lower set plate movable relative to the load lock body between a first lower set plate position and a second lower set plate position.

In addition to one or more of the features described above, or as an alternative, further examples may include that the upper heater is fixed to the upper accessory seat, that the lower heater may be fixed to the lower accessory seat, and that the intermediate accessory seat blanking plate is fixed to the intermediate accessory seat. The load lock arrangement may further include a first upper set plate arranged between the upper accessory seat and the intermediate accessory seat, the first upper set plate fixed relative to the load lock body; and a first lower set plate arranged between the lower accessory seat and the intermediate accessory seat, the first lower set plate fixed relative to the load lock body.

In addition to one or more of the features described above, or as an alternative, further examples may include that the upper chill plate is fixed to the intermediate accessory seat, that the lower chill plate may be fixed to the lower accessory seat, and that the upper accessory seat blanking plate may be fixed to the upper accessory seat. The load lock arrangement may further include a first upper set plate arranged between the upper accessory seat and the intermediate accessory seat, the first upper set plate movable relative to the load lock body between a first upper set plate position and a second lower set plate position; and a first lower set plate arranged between the lower accessory seat and the intermediate accessory seat, the first lower set plate movable relative to the load lock body between a first lower set plate position and a second lower set plate position.

A material layer deposition method is provided. The material layer deposition method includes, at a load lock arrangement as described above, transferring a substrate from an equipment front-end module into the load lock body, transferring the substrate from the load lock body into a process module, and depositing a material layer onto the substrate using the process module. The substrate is transferred from the process module to the load lock body and the substrate transferred from the load lock body to the equipment front-end module. The substrate is one of (a) heated while supported within the load lock body, (b) cooled while supported within the load lock body, or (c) retained at a substantially constant temperature while supported within the load lock body.

In addition to one or more of the features described above, or as an alternative, further examples the material layer deposition method may include that transferring the substrate from the equipment front-end module into the load lock body includes heating the substrate in the load lock body.

In addition to one or more of the features described above, or as an alternative, further examples may include that transferring the substrate from the process module into the load lock body may further include cooling the substrate while supported within the load lock body.

In addition to one or more of the features described above, or as an alternative, further examples may include that transferring the substrate from the equipment front-end module further includes maintaining the substrate at a substantially constant temperature within the load lock body, and wherein transferring the substrate from the process module comprises maintaining the substrate at a substantially constant temperature.

A method of making a load lock arrangement is also provided. The method of making the load lock arrangement includes, at a load lock arrangement as described above, fixing an upper heater to the upper accessory seat when substrate heating is required and fixing an upper accessory seat blanking plate fixed to the upper accessory seat when substrate heating is not required, fixing an upper chill plate to the intermediate accessory seat when substrate cooling is required and fixing an intermediate accessory seat blanking plate fixed to the intermediate accessory seat when substrate cooling is not required, and fixing a lower chill plate to the lower accessory seat when substrate cooling is required, fixing a lower heater to the lower accessory seat when substrate cooling is required, and fixing a lower accessory seat blanking plate to the lower accessory seat when neither substrate cooling nor substrate heating is required.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a plan view of a semiconductor processing system with a load lock arrangement in accordance with the present disclosure, schematically showing the load lock arrangement coupling an equipment front-end module to a process module;

FIGS. 2 and 3 are top plan and bottom plan views of the load lock arrangement of FIG. 1, schematically showing a front-end gate valves and back-end gate valves spaced apart from one another by upper and lower plate members of the load lock, respectively;

FIG. 4 and FIGS. 5 and 6 are front sectional and top plan views of a portion of the load lock arrangement of FIG. 1, showing upper and lower set plates arranged within an upper chamber and a lower chamber defined within the load lock body and an intermediate plate member of the load lock body, respectively;

FIGS. 7 and 8 are top plan views of a portion of the load lock arrangement of FIG. 1, showing upper accessory seat blanking plates and upper set plate actuators and heaters and upper actuator seat blanking plates fixed to an upper plate member of the load lock body, respectively;

FIGS. 9-11 are top plan views of a portion of the load lock arrangement of FIG. 1, showing lower accessory seat blanking plates, heaters, and chill plates fixed to lower accessory seats defined by a lower plate member of the load lock body, respectively;

FIG. 12 is sectional view of the load lock arrangement of FIG. 1, showing blanking plates fixed to accessory seats in an example of the load lock arrangement where neither substrate heating nor substrate cooling are required within the load lock arrangement;

FIG. 13 is sectional view of the load lock arrangement of FIG. 1 according to another example of the present disclosure, showing heaters and chill plates fixed to the accessory seats where both substrate heating and substrate cooling are required within the load lock arrangement;

FIG. 14 is a sectional view of the load lock arrangement of FIG. 1 according to a further example of the present disclosure, showing heaters fixed to accessory seats in both upper and lower chambers of the load lock arrangement where only substrate heating is required within the load lock arrangement;

FIG. 15 is a sectional view of the load lock arrangement of FIG. 1 according to another example of the present disclosure, showing chill plates fixed to accessory seats in both the upper and lower chambers of the load lock arrangement where only substrate cooling is required within the load lock arrangement;

FIGS. 16 and 17 are a block diagram of a method of making a load lock arrangement according to the present disclosure, showing operations of the method of making a load lock arrangement for a semiconductor processing system according to an illustrative and non-limiting example of the method; and

FIG. 18 is a block diagram of a material layer deposition method according to the present disclosure, showing operations of the material layer deposition method according to an illustrative and non-limiting example of the method.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

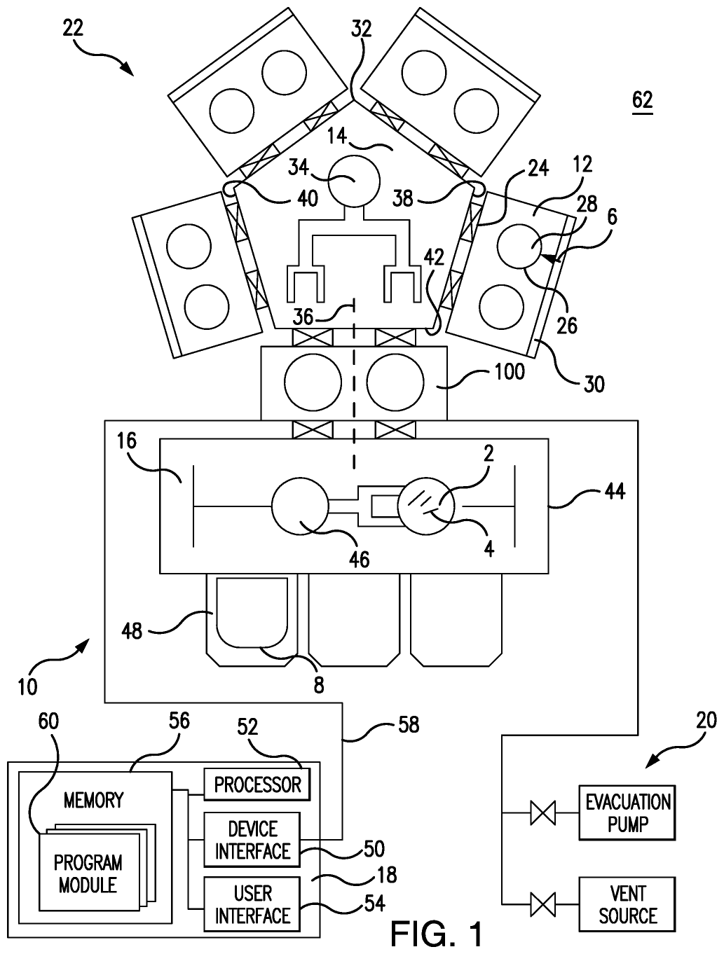

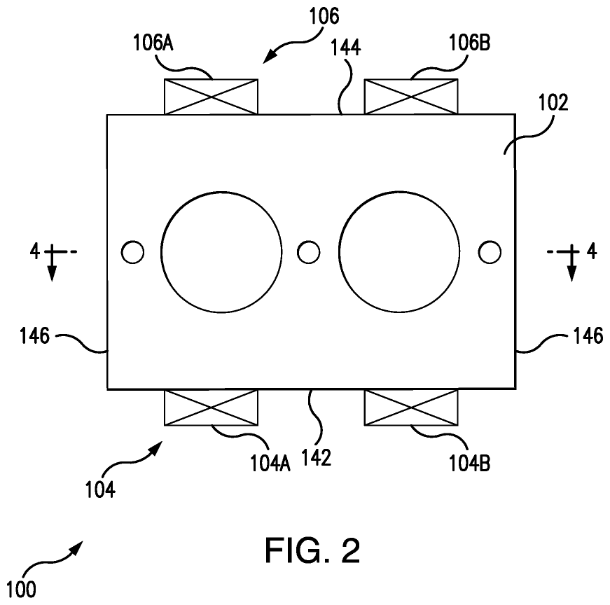

Reference will now be made to the drawings wherein like reference numerals identify similar structural features or aspects of the subject disclosure. For purposes of explanation and illustration, and not limitation, a partial view of a load lock arrangement coupling a process module to an equipment front-end module (EFEM) of a semiconductor processing system in accordance with the present disclosure is shown in FIG. 1 and is designated generally by reference character 100. Other examples of load lock arrangements, semiconductor processing systems having load lock arrangements, material layer deposition methods, and methods of making load lock arrangements in accordance with the present disclosure, or aspects thereof, are provided in FIGS. 2-18, as will be described. The systems and methods of the present disclosure may be in semiconductor processing systems employed to fabricate semiconductor devices, such as in semiconductor processing systems employed to deposit material layers using chemical vapor deposition (CVD) and atomic layer deposition (ALD) techniques during the fabrication of logic and memory devices, though the present disclosure is not limited to any semiconductor processing operation or to the fabrication of any particular semiconductor device in general.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Wafers may be 200 millimeters in diameter, 300 millimeters, or even 450 millimeters in diameter. Substrates may be formed from one or more semiconductor materials including by way of non-limiting example silicon, silicon germanium, silicon oxide, gallium arsenide, gallium nitride and silicon carbide.

Referring to FIG. 1, a semiconductor processing system 10 is shown. The semiconductor processing system 10 includes a process module 12, a back-end transfer module 14, and the load lock arrangement 100. The semiconductor processing system 10 also includes an EFEM 16, a controller 18, and an evacuation/venting source 20. In the illustrated example the semiconductor processing system 10 includes a cluster-type platform 22 with four (4) process modules configured to deposit a material layer 4 onto a substrate 2 using an atomic layer deposition (ALD) technique. This is for illustration and description purposes only and is non-limiting. As will be appreciated by those of skill in the art in view of the present disclosure, semiconductor processing systems configured for other material layer deposition operations as well as semiconductor processing systems configured for processing operations other than material layer deposition can also benefit from the present disclosure.

The process module 12 is coupled to the back-end transfer module 14 by a process module gate valve 24 and includes a process chamber 26, a heater 28, and a reactant source 30. The process chamber 26 is arranged within the process module 12, houses the heater 28, and is configured to flow a material layer precursor or reactant 6 across the substrate 2 while seated on the heater 28 during deposition of the material layer 4 onto the substrate 2. The reactant source 30 is fluidly coupled to the process chamber 26 and configured to provide the reactant 6 to the process chamber 26 for deposition of the material layer 4 onto the substrate 2. The process module gate valve 24 couples the process module 12 to the back-end transfer module 14 and is configured to provide selective communication between the process chamber 26 and the back-end transfer module 14. In this respect it is contemplated that the process module gate valve 24 be configured to permit transfer of the substrate 2 between the back-end transfer module 14 and the process module 12 before and after deposition of the material layer 4 onto the substrate 2.

In certain examples the process chamber 26 may be a first process chamber and the process module 12 may include one or more second process chamber. For example, the process module 12 may be a dual chamber module having two (2) process chambers or a quad chamber module having four (4) process chambers. In accordance with certain examples, the process module gate valve 24 may be a first process module gate valve and the process module 12 may include a second process module gate valve also coupling the process module 12 to the back-end transfer module 14. It is contemplated that, in certain examples, the reactant 6 may include a reactant or a precursor suitable for deposition of the material layer 4, such as using an ALD or a CVD deposition technique. It is also contemplated that, in accordance with certain examples, the process module 12 include a plasma unit configured to provide the reactant 6 to the substrate 2 as a plasma suitable. In this respect the process module 12 may be configured to deposit in the material layer 4 onto the substrate 2 using a PEALD or a PECVD technique by way of example.

The back-end transfer module 14 is coupled to the load lock arrangement 100 and includes a back-end chamber body 32 and a back-end substrate transfer robot 34. The back-end chamber body 32 is arranged along a transfer axis 36 and has a first process module facet 38, one or more second process module facet 40, and a load lock facet 42. The first process module facet 38 and the second process module facet 40 are angled (e.g., an oblique angle) relative to the transfer axis 36. The first process module facet 38 further couples the back-end chamber body 32 to the process module 12. The load lock facet 42 couples the first process module facet 38 to the second process module facet 40 and further intersects the transfer axis 36. The load lock facet 42 may be substantially orthogonal relative to the transfer axis 36, and may further couple the load lock arrangement 100 to the back-end chamber body 32. It is contemplated that the back-end substrate transfer robot 34 be arranged within an interior of the back-end chamber body 32 and supported within the back-end chamber body 32 for movement relative to the back-end chamber body 32 for transfer of substrates, e.g., the substrate 2, between the load lock arrangement 100 and the process module 12. In certain examples, the back-end chamber body 32 may have a polygonal shape. In this respect the back-end chamber body 32 may have five sides, fewer than five sides (e.g., a rectangular or square shape), or more than five sides (e.g., a hexagonal shape), and may have the shape of a regular polygon or an irregular polygon.

The EFEM 16 is coupled to the load lock arrangement 100 includes an enclosure 44, a front-end substrate transfer robot 46, and one or more load port 48. The enclosure 44 houses the front-end substrate transfer robot 46. The front-end substrate transfer robot 46 is within the enclosure 44 for movement relative to the enclosure 44 for transfer of substrates, e.g., the substrate 2, between the one or more load port 48 and the load lock arrangement 100. The one or more load port 48 is connected to the enclosure 44 and is configured to seat there a pod 8 housing one or more substrates, e.g., the substrate 2, prior to and subsequent to deposition of material layers, e.g., the material layer 4, onto the substrates. In certain examples, the pod 8 may include a standard mechanical interface pod. In accordance with certain examples, the pod 8 may include a front-opening unified pod. Although shown and described herein as having three (3) load ports it is to be understood and appreciated that EFEM 16 may include fewer or additional load ports and remain within the scope of the present disclosure.

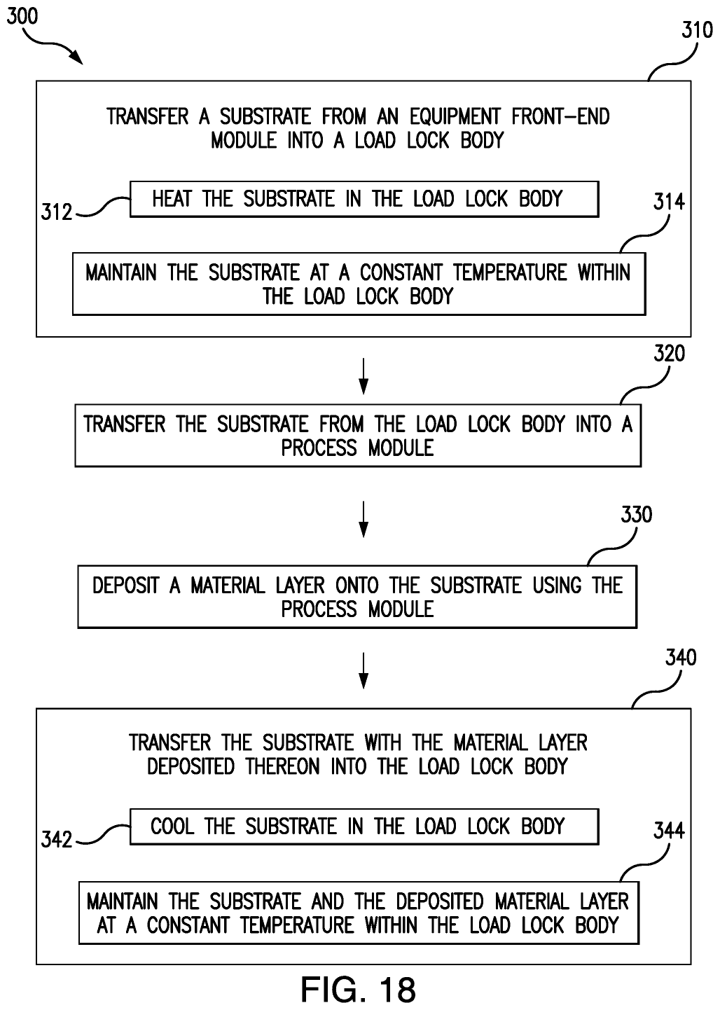

The controller 18 is operably connected to the semiconductor processing system 10 and includes a device interface 50, a processor 52, a user interface 54, and a memory 56. The device interface 50 couples the processor 52 to the semiconductor processing system 10, for example, through (or over) a wired or wireless link 58. The processor 52 is operably connected to the user interface 54 and is disposed in communication with the memory 56. The memory 56 includes a non-transitory machine-readable medium having a plurality of program modules 60 recorded thereon containing instructions that, when read by the processor 52, cause the processor to execute certain operations. Among the operations are operations of a material layer deposition method 300 (shown in FIG. 18), as will be described.

As has been explained above, some semiconductor processing systems require substrate heating and/or substrate cooling within the system load lock, such as for throughput purposes. For example, in some semiconductor processing systems, substrate heating within the system load lock may be required to limit processing time within the process module to shorten the time required to ramp substrate temperature to a desired material layer deposition temperature. Alternatively or additionally, substrate cooling within the system load locks may be required to limit processing time within the system process modules to limit time otherwise required for substrate cooling in the process modules following material layer deposition. While substrate cooling and/or substrate heating requirements can be me through customization of the load for a particular requirement, customization can lead to increased cost due to reduction in economies of scale and complexity. To meet the requirements for substrate cooling and/or substrate cooling without customization, as well as meet the need for load locks where substrate heating and substrate cooling are not required, the load lock arrangement 100 is provided.

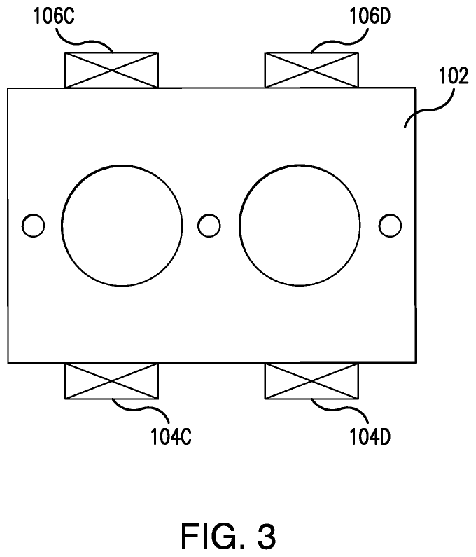

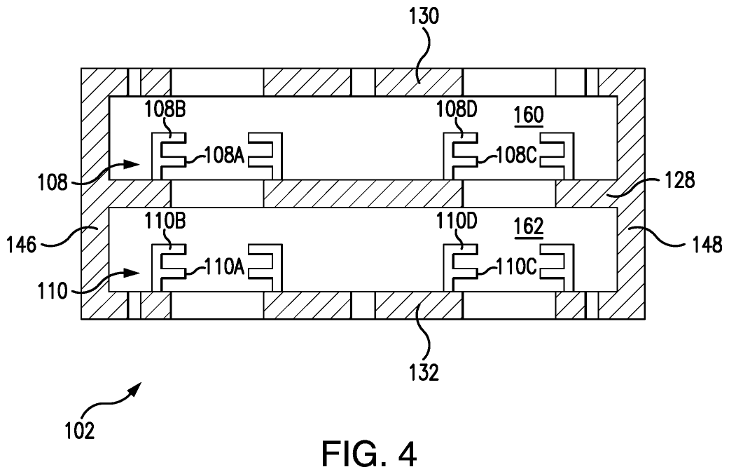

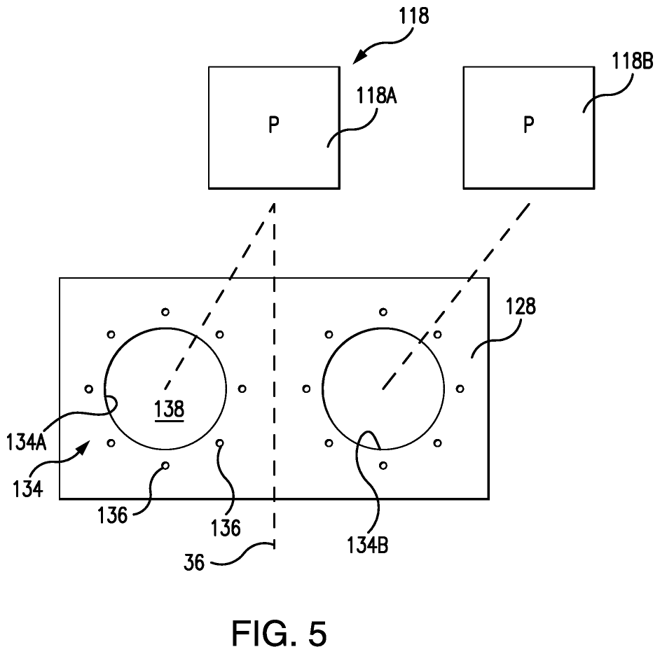

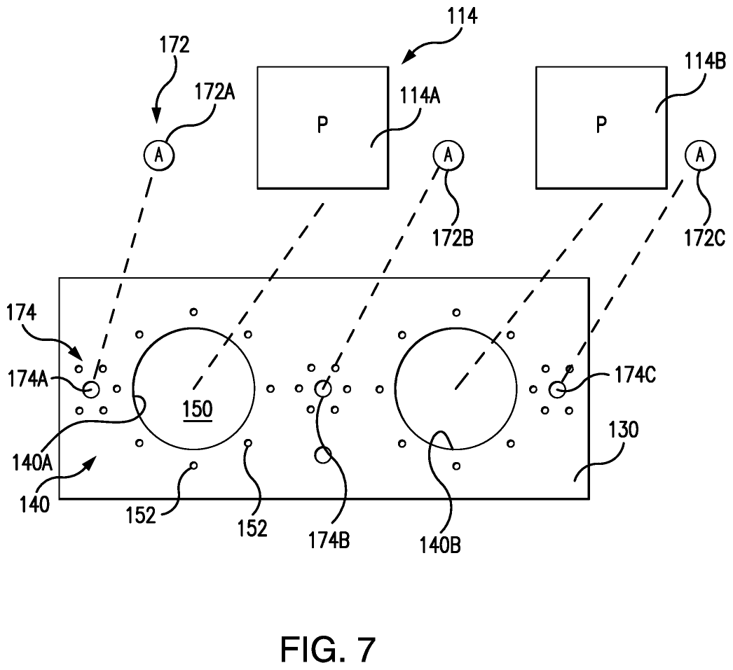

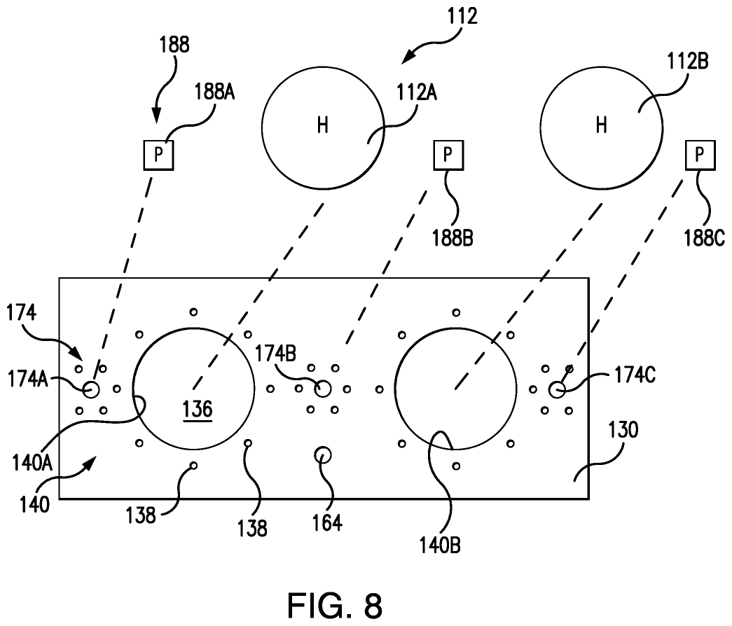

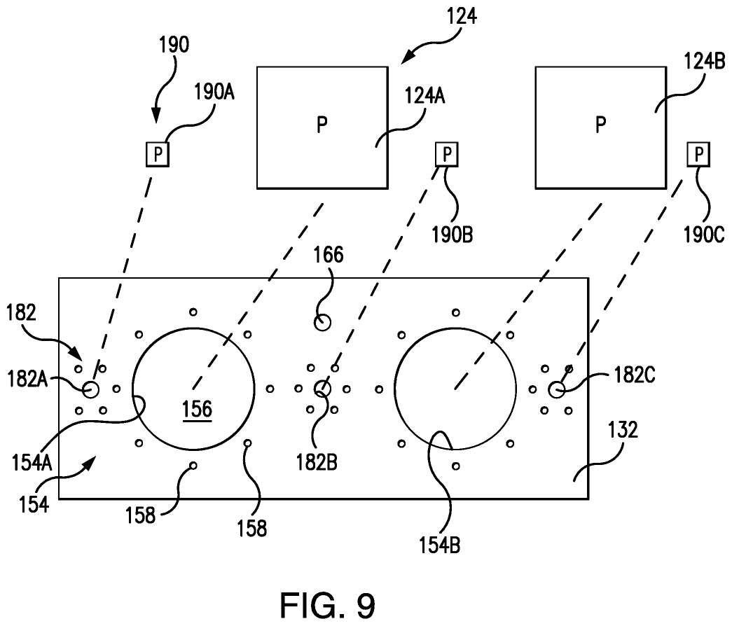

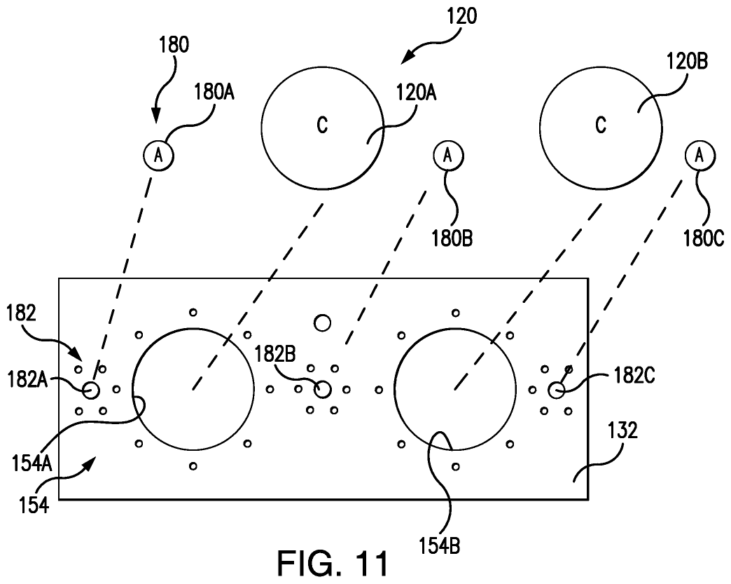

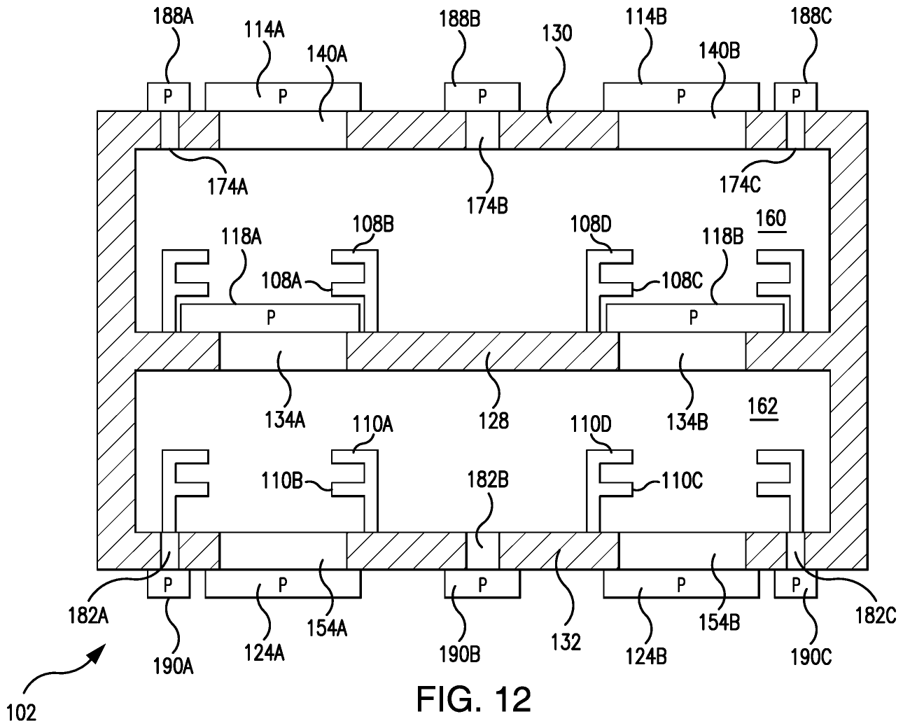

With reference to FIGS. 2 and 3, the load lock arrangement 100 is shown in plan and bottom views, respectively. As shown in FIG. 2, the load lock arrangement 100 includes a load lock body 102, a front-end gate valve 104, and a back-end gate valve 106. The load lock arrangement 100 also includes an upper set plate 108 (shown in FIG. 12), a lower set plate 110 (shown in FIG. 12), and one of an upper heater 112 (shown in FIG. 5) and a upper accessory seat blanking plate 114 (shown in FIG. 4). The load lock arrangement 100 further includes one of an upper chill plate 116 (shown in FIG. 8) and an intermediate accessory seat blanking plate 118 (shown in FIG. 7); one of a lower chill plate 120 (shown in FIG. 11), a lower heater 122 (shown in FIG. 12), and a lower accessory seat blanking plate 124 (shown in FIG. 9); and an optional thermal barrier 126 (shown in FIG. 8). Although the load lock arrangement 100 is shown and described herein as having particular arrangements, it is to be understood and appreciated that the load lock arrangement may have a different arrangement is other examples and remain within the scope of the present disclosure.

The front-end gate valve 104 couples the load lock arrangement 100 to the EFEM 16 (shown in FIG. 1) and provides selective communication between the load lock arrangement 100 and the EFEM 16. In this respect it is contemplated that the front-end gate valve 104 enable transfer of substrates, e.g., the substrate 2 (shown in FIG. 1), between the load lock arrangement 100 and the EFEM 16 when the load lock body 102 is at substantially the same pressure as the interior of the enclosure 44 (shown in FIG. 1). In further respect the front-end gate valve 104 may open when the evacuation/venting source 20 (shown in FIG. 1) has vented the load lock arrangement 100. In the illustrated example the front-end gate valve 104 is a first front-end gate valve 104A and the load lock arrangement 100 includes a second front-end gate valve 104B coupling the load lock arrangement 100 to the EFEM 16. As shown in FIG. 3, the load lock arrangement 100 also includes a third front-end gate valve 104C, and a fourth front-end gate valve 104D each coupling the load lock arrangement 100 to the EFEM 16. As will be appreciated by those of skill in the art in view of the present disclosure, other arrangements are possible and remain within the scope of the present disclosure.

With continuing reference to FIG. 2, the back-end gate valve 106 is similar to the back-end gate valve 106, additionally couples the load lock arrangement 100 to the back-end transfer module 14 (shown in FIG. 1), and provides selective communication between the load lock arrangement 100 and the back-end transfer module 14. In this respect it is contemplated that the back-end gate valve 106 enable transfer of substrates, e.g., the substrate 2 (shown in FIG. 1), between the load lock arrangement 100 and the back-end transfer module 14 when the load lock body 102 is at substantially the same pressure as the interior of the back-end chamber body 32 (shown in FIG. 1). In further respect the back-end gate valve 106 may open when the evacuation/venting source 20 (shown in FIG. 1) has evacuated the load lock arrangement 100 such pressure within the load lock body 102 is substantially equivalent to that within the back-end chamber body 32. In the illustrated example the back-end gate valve 106 is a first back-end gate valve 106A and the load lock arrangement 100 includes a second back-end gate valve 106B coupling the load lock arrangement 100 to the back-end transfer module 14 (shown in FIG. 1). As shown in FIG. 3, the load lock arrangement may also include a third back-end gate valve 106C, and a fourth back-end gate valve 106D each coupling the load lock arrangement 100 to the back-end transfer module 14. As will be appreciated by those of skill in the art in view of the present disclosure, other arrangements are possible and remain within the scope of the present disclosure.

With reference to FIG. 4, the load lock body 102 is shown in a section view. In the illustrated example the load lock body includes an intermediate plate member 128, an upper plate member 130, and a lower plate member 132. The upper plate member 130 is arranged above the intermediate plate member 128, is spaced apart from the intermediate plate member 128 by an upper chamber 160, and is coupled to the intermediate plate member by a front-end wall 142 (shown in FIG. 2), a back-end wall 144 (shown in FIG. 2), a first sidewall 146, and a second sidewall 148. The lower plate member 132 is supported below the intermediate plate member 128 and is spaced apart from the intermediate plate member 128 by a lower chamber 162. The lower plate member 132 is further coupled to the intermediate plate member 128 by the front-end wall 142, the back-end wall 144, the first sidewall 146, and the second sidewall 148. It is contemplated that the first front-end gate valve 104A (shown in FIG. 2) and the second front-end gate valve 104B (shown in FIG. 2) be fixed to the front-end wall 142 to provide selective communication with the upper chamber 160, that the first back-end gate valve 106A (shown in FIG. 2) and the second back-end gate valve 106B (shown in FIG. 2) be fixed to the back-end wall 144 to provide selective communication with the upper chamber 160, that the third front-end gate valve 104C (shown in FIG. 3) and the fourth front-end gate valve 104D (shown in FIG. 3) be fixed to the front-end wall 142 to provide selective communication with the lower chamber 162, and that that the third back-end gate valve 106C (shown in FIG. 3) and the fourth back-end gate valve 106D (shown in FIG. 3) be fixed to the back-end wall 144 to provide selective communication with the lower chamber 162.

The upper set plate 108 is arranged within the upper chamber 160 of the load lock body 102 and is configured to support a substrate, e.g., the substrate 2 (shown in FIG. 1), within the upper chamber 160. In the illustrated example the upper set plate 108 is a first upper set plate 108A and the load lock arrangement 100 includes a second upper set plate 108B, a third upper set plate 108C, and a fourth upper set plate 108D. The second upper set plate 108B is similar to the first upper set plate 108A and is additionally stacked (e.g., fixed) on the first upper set plate 108A within the upper chamber 160. The third upper set plate 108C and the fourth upper set plate 108D are also similar to the first upper set plate 108A, the third upper set plate 108C additionally separated from the first upper set plate 108A by the transfer axis 36 (shown in FIG. 1), and the fourth upper set plate 108D stacked (e.g., fixed) on the third upper set plate 108C.

The lower set plate 110 is arranged within the lower chamber 162 of the load lock body 102 and is also configured to support a substrate, e.g., the substrate 2 (shown in FIG. 1), within the lower chamber 162 of the load lock body 102. In the illustrated example the lower set plate 110 is a first lower set plate 110A and the load lock arrangement 100 includes a second lower set plate 110B, a third lower set plate 110C, and a fourth lower set plate 110D. The second lower set plate 110B is similar to the first lower set plate 110A and is additionally stacked (e.g., fixed) on the first lower set plate 110A within the lower chamber 162 of the load lock body 102. The third lower set plate 110C and the fourth lower set plate 110D are also similar to the first lower set plate 110A, the third lower set plate 110C additionally separated from the first lower set plate 110A by the transfer axis 36 (shown in FIG. 1), and the fourth lower set plate 110D stacked (e.g., fixed) on the third lower set plate 110C.

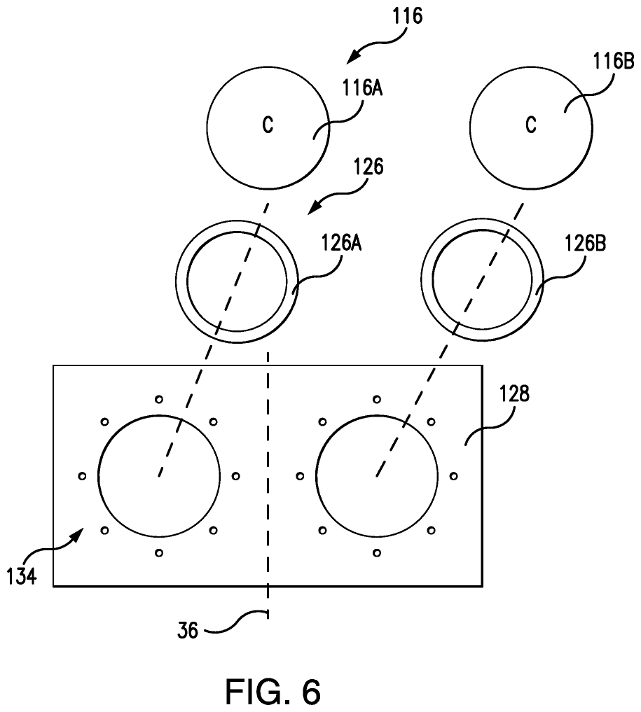

With reference to FIGS. 5 and 6, the intermediate plate member 128 is shown in plan view. As shown in FIG. 5, the intermediate plate member 128 is arranged along the transfer axis 36 and defines one or more intermediate accessory seat 134. The intermediate accessory seat 134 is configured and adapted for alternative fixation thereon the upper chill plate 116 and the intermediate accessory seat blanking plate 118 and in this respect may include an intermediate accessory seat aperture 138 and an intermediate accessory seat fastener pattern 138. The intermediate accessory seat 134 may be laterally aligned to the front-end gate valve 104 (shown in FIG. 2). The intermediate accessory seat 134 may be laterally aligned to the back-end gate valve 106 (shown in FIG. 2). As will be appreciated by those of skill in the art in view of the present disclosure, lateral alignment of the intermediate accessory seat 134 to front-end gate valve 104 and/or the back-end gate valve 106 may facilitate transfer of substrates, e.g., the substrate 2 (shown in FIG. 1), between the EFEM 16 (shown in FIG. 1) and the back-end transfer module 14, for example, by limiting movements required by the front-end substrate transfer robot 46 (shown in FIG. 1) and the back-end substrate transfer robot 34 (shown in FIG. 1), increasing throughput of the semiconductor processing system 10 (shown in FIG. 1).

In certain examples the intermediate accessory seat 134 may be a first intermediate accessory seat 134A and the intermediate plate member 128 may define a second intermediate accessory seat 134B. The second intermediate accessory seat 134B may be similar to the first intermediate accessory seat 134A and additionally laterally offset from the first intermediate accessory seat 134A (e.g., at a location separated from the first intermediate accessory seat 134A by the transfer axis 36) in such examples. The second intermediate accessory seat 134B may be further registered with the second front-end gate valve 104B (shown in FIG. 2) and the second back-end gate valve 106B (shown in FIG. 2). Lateral alignment of the intermediate accessory seat 134 to second front-end gate valve 104B and/or the second back-end gate valve 106B may also facilitate transfer of substrates, e.g., the substrate 2 (shown in FIG. 1), between the EFEM 16 (shown in FIG. 1) and the back-end transfer module 14 by limiting movements required by the front-end substrate transfer robot 46 (shown in FIG. 1) and the back-end substrate transfer robot 34 (shown in FIG. 1), increasing throughput of the semiconductor processing system 10 (shown in FIG. 1).

In certain examples the intermediate accessory seat blanking plate 118 may be fixed to the intermediate accessory seat 134, for example, in examples of the load lock arrangement 100 (shown in FIG. 1) where substrate heating is not required within the upper chamber 160 (shown in FIG. 4) of the load lock body 102 (shown in FIG. 2). The intermediate accessory seat blanking plate 118 may provide fluid separate between the upper chamber 160 (shown in FIG. 4) and the lower chamber 162 (shown in FIG. 4) of the load lock body 102 (shown in FIG. 2), the upper chamber 160 thereby being fluidly isolated from the lower chamber 162, fluid isolating facilitating scheduling of substrates through the load lock arrangement 100 (shown in FIG. 1). The intermediate accessory blanking plate 118 may include a plug member. The plug member may be threadedly received within the intermediate accessory seat 134, the plug member limiting height and/or internal volume of the load lock body 102 in such examples.

In certain examples the intermediate accessory seat blanking plate 118 may be a first intermediate accessory seat blanking plate 118A and the load lock arrangement 100 may include a second intermediate accessory seat blanking plate 118B. The second intermediate accessory seat blanking plate 118B may be similar to the first intermediate accessory seat blanking plate 118A in such examples. The second intermediate accessory seat blanking plate 118B may additionally be fixed to the second intermediate accessory seat 134B. The first intermediate accessory seat blanking plate 118A and the second intermediate accessory seat blanking plate 118B may fluidly separate the upper chamber 160 from the lower chamber 162 defined within the load lock body 102, the upper chamber 160 being fluidly isolated from the lower chamber in such examples.

As shown in FIG. 6, an upper chill plate 116 may be fixed to the intermediate accessory seat 134 in examples of the load lock arrangement 100 (shown in FIG. 1) where substrate heating is required within the upper chamber 160 (shown in FIG. 4). The upper chill plate 116 may be configured to cool a substrate, e.g., the substrate 2 (shown in FIG. 1), supported above an upper surface of the upper chill plate 116 using a coolant circulate through the upper chill plate 116. In certain examples, a thermal barrier 126 may be compressively fixed between the upper chill plate 116 and the intermediate plate member 128 at the intermediate accessory seat 134. The thermal barrier 126 may thermally separate the upper chill plate 116 from the intermediate plate member 128 and thereby from the load lock body 102, chilling thereby limited to the substrates supported above the upper chill plate 116 within the upper chamber 160 of the load lock body 102.

In accordance with certain examples, the upper chill plate 116 may be a first upper chill plate 116A and the load lock arrangement 100 may include a second upper chill plate 116B. The second upper chill plate 116B may be similar to the first upper chill plate 116A, may additionally be fixed to the second intermediate accessory seat 134B, and may further be configured to cool a second substrate supported within the upper chamber 160 of the load lock body 102. It is also contemplated that, in accordance with certain examples, the thermal barrier 126 may be a first thermal barrier 126A, and the load lock arrangement 100 (shown in FIG. 1) may include a second thermal barrier 126B. The second thermal barrier 126B may be similar to the first thermal barrier 126A in such examples, the second thermal barrier 126B additionally compressively fixed between the second upper chill plate 116B at the second intermediate accessory seat 134B to limit thermal communication between the second upper chill plate 116B and the load lock body 102.

With reference to FIGS. 7 and 8, the upper plate member 130 is shown in plan view. The upper plate member 130 is similar to the intermediate plate member 128 (shown in FIG. 4) and is spaced apart from the intermediate plate member 128 by the upper chamber 160 (shown in FIG. 4). The upper plate member 130 is further coupled to the intermediate plate member 128 by one or more of a front-end wall 142 (shown in FIG. 2), a back-end wall 144 (shown in FIG. 2), a first sidewall 146 (shown in FIG. 2), and a second sidewall 148 (shown in FIG. 2). The upper plate member 130 further defines an upper accessory seat 140 and an upper set plate actuator seat 174. In certain examples the intermediate plate member 128 and one or more of the front-end wall 142, the back-end wall 144, the first sidewall 146, and the second sidewall 148 may be formed from a common piece of stock. In this respect a portion of the load lock body 102 including the intermediate plate member 128 may be formed from a common piece of stock using a subtractive technique, and the upper plate member 130 fixed using fasteners or welding. In further respect the portion of load lock body 102 may be formed using an additive technique and the upper plate member 130 fixed to the intermediate plate member 128 through the one or more of the front-end wall 142, the back-end wall 144, the first sidewall 146, and the second sidewall 148.

The upper accessory seat 140 is configured and adapted for alternative fixation thereon the upper accessory seat blanking plate 114 and upper heater 112 (shown in FIG. 8) and in this respect may include an upper accessory seat aperture 150 and an upper accessory seat fastener pattern 152. The upper accessory seat 140 may be laterally aligned to the first front-end gate valve 104A (shown in FIG. 2). The upper accessory seat 140 may be laterally aligned to the first back-end gate valve 106A (shown in FIG. 2). The upper accessory seat 140 may be vertically registered with the intermediate accessory seat 134 (shown in FIG. 5), for example, such that the upper accessory seat 140 overlays the substrate 2 when supported within the upper chamber 160 (shown in FIG. 4) of the load lock body 102 (shown in FIG. 2). As will be appreciated by those of skill in the art in view of the present disclosure, lateral alignment of the upper accessory seat 140 with either (or both) the first front-end gate valve 104A and the first back-end gate valve 106A may simplify transfer of substrates into and out of the upper chamber 160 of the load lock body 102. As will also be appreciated by those of skill in the art in view of the present disclosure, registration of the upper accessory seat 140 with the intermediate accessory seat 134 may facilitate substrate heating and/or substrate cooling in examples of the load lock arrangement 100 (shown in FIG. 1) where substrate heating and/or substrate in the upper chamber 160 of the load lock body 102 is required.

In certain examples, the upper accessory seat 140 may be a first upper accessory seat 140A and the upper plate member 130 may define a second upper accessory seat 140B. The second upper accessory seat 140B may be similar to the first upper accessory seat 140A and additionally be laterally offset from the first upper accessory seat 140A, for example, on a side of the transfer axis 36 (shown in FIG. 1) opposite that of the first upper accessory seat 140A. The second upper accessory seat 140B may be laterally aligned to the second front-end gate valve 104B (shown in FIG. 2). The second upper accessory seat 140B may be laterally aligned to the second back-end gate valve 106B (shown in FIG. 2). The second upper accessory seat 140B may be vertically registered with the second intermediate accessory seat 134B (shown in FIG. 5), for example, such that the second upper accessory seat 140B overlays the substrate 2 (shown in FIG. 1) when the substrate 2 is supported within the upper chamber 160 (shown in FIG. 4) of the load lock body 102 (shown in FIG. 2). As will be appreciated by those of skill in the art in view of the present disclosure, lateral alignment of the second upper accessory seat 140B with either (or both) the second front-end gate valve 104B and the second back-end gate valve 106B may simplify transfer of the substrate 2 into and out of the upper chamber 160 of the load lock body 102. As will also be appreciated by those of skill in the art in view of the present disclosure, registration of the second upper accessory seat 140B with the second intermediate accessory seat 134B may also facilitate heating and/or cooling of the substrate 2 in examples of the load lock arrangement 100 (shown in FIG. 1) when substrate heating and/or substrate cooling in the upper chamber 160 of the load lock body 102 is required.

In examples where substrate heating within the upper chamber 160 is not required the upper accessory seat blanking plate 114 may be fixed to the upper accessory seat 140. The upper accessory seat blanking plate 114 may fluidly separate the upper chamber 160 of the load lock body 102 from an external environment 62 (shown in FIG. 1) outside of the load lock body 102, the upper chamber 160 thereby being fluidly isolated from the external environment 62. A gasket or sealing member may compressively fixed between the upper accessory seat blanking plate 114 and the upper plate member 130 at the upper accessory seat 140, the gasket or sealing member cooperating with the upper accessory seat blanking plate 114 to fluidly separate the upper chamber 160 from the external environment 62 in such examples. It is contemplated that the upper accessory seat blanking plate 114 may be fixed to an interior surface of the upper plate member 130, interior fixation limiting (or eliminating) turbulence within the upper chamber 160 during evacuation and/or venting of the upper chamber 160. It is also contemplated that the upper accessory seat blanking plate 114 may be fixed to an exterior surface of the upper plate member 130 and include a plug body occupying the upper accessory seat aperture 150, exterior fixation simplifying fabrication of the load lock arrangement 100 (shown in FIG. 1) and the plug body limiting (or eliminating) turbulence within the upper chamber 160.

In certain examples the upper accessory seat blanking plate 140 may be a first upper accessory seat blanking plate 114A and the load lock arrangement 100 (shown in FIG. 1) may include a second upper accessory seat blanking plate 114B. The second upper accessory seat blanking plate 114B may be similar to the first upper accessory seat blanking plate 114A and may additionally be fixed to the upper plate member 130 at the second upper accessory seat 140B. The second upper accessory seat blanking plate 114B may also fluidly separate the upper chamber 160 from the external environment 62 (shown in FIG. 1) outside of the load lock arrangement 100. As shown in FIG. 8, in examples where substrate heating within the upper chamber 160 is required, the upper heater 112 may be fixed to the upper accessory seat 140. The upper heater 112 may be configured to radiantly heat a substrate supported within the upper chamber 160, e.g., the substrate 2 (shown in FIG. 1), and this respect may include one or more radiant heating device optically coupled the interior of the upper chamber 160, such as an infrared lamp. As will be appreciated by those of skill in the art in view of the present disclosure, employment of radiant heating device avoids the need to rely on conduction and/or or convection to heat substrates supported within the upper chamber 160, increasing throughput by enabling substrate heating during evacuation and/or venting of the upper chamber 160.

In certain examples the upper heater 112 may be a first upper heater 112A and the load lock arrangement 100 (shown in FIG. 1) may include a second upper heater 112B. The second upper heater 112B may be similar to the first upper heater 112A and additionally fixed to the upper plate member 130 at the second upper accessory seat 140B to heat a substrate, e.g., the substrate 2 (shown in FIG. 1), supported within the upper chamber 160 (shown in FIG. 4) of the load lock body 102 (shown in FIG. 2). The second upper heater 112B may be laterally separated from the first upper heater 112A by an upper evacuation/venting port 164. The upper evacuation/venting port 164 may be fluidly coupled to the evacuation/venting source 20 (shown in FIG. 1) for evacuation/venting of the upper chamber 160, for example, independently of the lower chamber 162 (shown in FIG. 4) of the load lock body 102, providing scheduling flexibility to the semiconductor processing system 10. Although shown and described herein as having two (2) upper accessory seats and including two (2) upper heaters, it is to be understood and appreciated that the load lock arrangement 100 (shown in FIG. 1) may have a single or more than or additional upper accessory seats and upper heaters and remain within the scope of the present disclosure.

In certain examples the upper evacuation/venting port 164 may further be symmetrically located within the upper chamber 160 at a position between the first upper accessory seat 140A and the second upper accessory seat 140B, for example at a location overlaying the transfer axis 36 (shown in FIG. 1). As will be appreciated by those of skill in the art in of the present disclosure, symmetrical positioning of the upper evacuation/venting port 164 may limit tendency of fluid flow within the upper chamber 160 from displacing substrates supported within the upper chamber 160 during evacuation/venting of the upper chamber 160, limiting (or eliminating) the tendency of such flows to generate backside artifacts (e.g., scratches) on the substrates. As will also be appreciated by those of skill in the art in view of the present disclosure, symmetrical positioning may also simplify the arrangement of the upper set plate 108, for example, by limiting (or eliminating) the need to constrain substrate position during evacuation/venting, simplifying the load lock arrangement 100 (shown in FIG. 1).

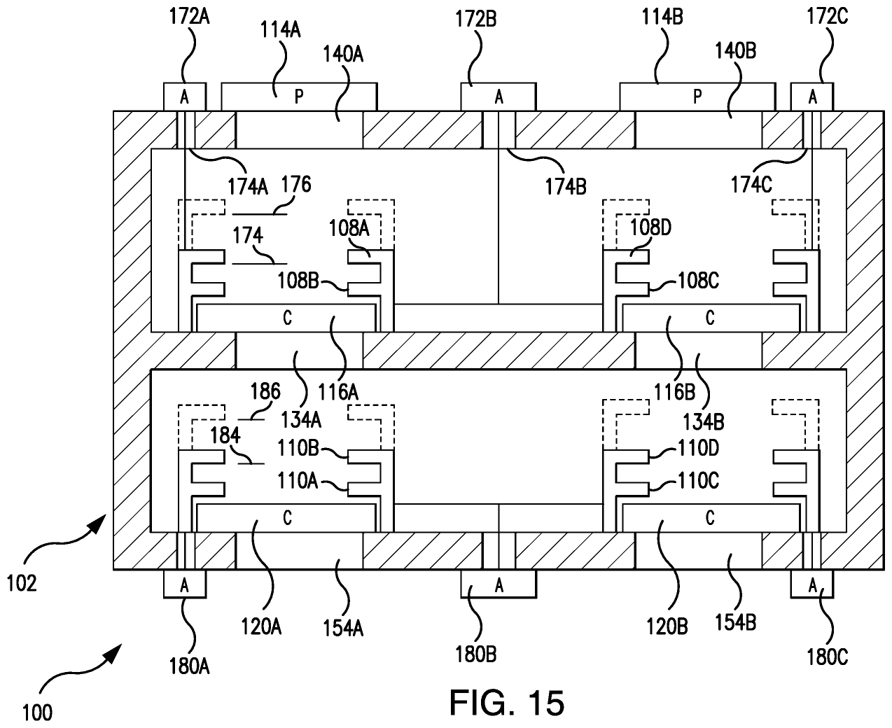

With continuing reference to FIG. 7, the upper plate member 130 may, in certain examples (e.g., in examples where substrate cooling is required), define an upper set plate actuator seat 174. The upper set plate actuator seat 174 may be similar to the upper accessory seat 140, e.g., include an upper actuator aperture and an upper actuator fastener pattern, and may be configured for fixation thereon an upper set plate actuator 172. The upper set plate actuator 172 in turn may be operatively connected to the upper set plate 108 (shown in FIG. 4) and configured to move the upper set plate 108 between a first upper set plate position 176 (shown in FIG. 15) and a second upper set plate position 178 (shown in FIG. 15), for example, to throttle rate of substrate heating and/or substrate cooling within the upper chamber 160 (shown in FIG. 4) of the load lock body 102 (shown in FIG. 2).

In certain examples the upper set plate actuator seat 174 may be a first upper set plate actuator seat 174A and the upper plate member 130 may define a second upper set plate actuator seat 174B and a second upper set plate actuator seat 174C. The second upper set plate actuator seat 174B and the third upper set plate actuator seat 174C may be similar to the first upper set plate actuator seat 174A, the second upper set plate actuator seat 174B configured for fixation thereto a second upper set plate actuator 172B, the third upper set plate actuator seat 174C configured for fixation thereto a third upper set plate actuator 172C, the second upper set plate actuator 172B and the third upper set plate actuator 172C configured to move the upper set plate 108 between the first upper set plate position 176 and the second upper set plate position 178 in cooperation with the first upper set plate actuator 172A. Although shown and described herein as having three (3) actuator seats and three (3) upper set plate actuators, it is to be understood and appreciated that the load lock arrangement 100 (shown in FIG. 1) may have fewer or additional actuator seats and upper set plate actuators and remain within the scope of the present disclosure.

Referring again to FIG. 8, the load lock arrangement 100 (shown in FIG. 1) may, in certain examples (e.g. in examples where substrate cooling in the upper chamber 160 is not required), include an upper actuator seat blanking plate 188. The upper actuator seat blanking plate 188 may be similar to the upper accessory seat blanking plate 114 (shown in FIG. 7) and additionally be fixed to the upper set plate actuator seat 174. In accordance with certain examples, the upper actuator seat blanking plate 188 may be a first upper actuator seat blanking plate 188A, and the load lock arrangement 100 may include a second upper actuator seat blanking plate 188B and a third upper actuator seat blanking plate 188C. The second upper actuator seat blanking plate 188B and the third upper actuator seat blanking plate 188C may be similar to the first upper actuator seat blanking plate 188A, the second upper actuator seat blanking plate 188B fixed to the second upper set plate actuator seat 174B, the third upper actuator seat blanking plate 188C fixed to the third upper set plate actuator seat 174C.

With reference to FIGS. 9-11, the lower plate member 132 is shown in plan view. As shown in FIG. 9, the lower plate member 132 is similar to the intermediate plate member 128 (shown in FIG. 4) and is additionally spaced apart from the intermediate plate member 128 by the lower chamber 162 (shown in FIG. 4). The lower plate member 132 is further coupled to the intermediate plate member 128 by one or more of a front-end wall 142 (shown in FIG. 2), a back-end wall 144 (shown in FIG. 2), a first sidewall 146 (shown in FIG. 2), and a second sidewall 148 (shown in FIG. 2). It is contemplated that the lower plate member 132 further define a lower accessory seat 154 and a lower set plate actuator seat 182.

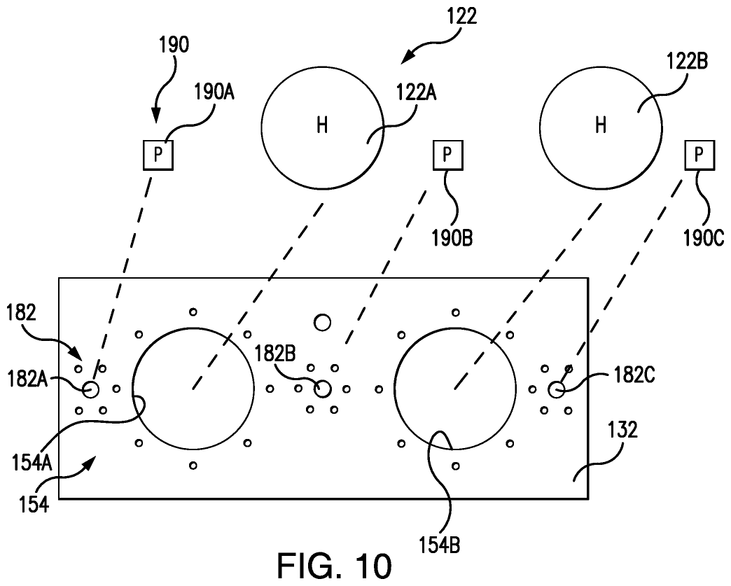

The lower accessory seat 154 is configured and adapted for alternative fixation thereon the lower accessory seat blanking plate 124, the lower heater 122 (shown in FIG. 10), and the lower chill plate 120 (shown in FIG. 11) and in this respect may include a lower accessory seat aperture 156 and a lower accessory seat fastener pattern 158. The lower accessory seat 154 may, in certain examples, be laterally aligned to the third front-end gate valve 104C (shown in FIG. 3). In accordance with certain examples, the lower accessory seat 154 may be laterally aligned to the third back-end gate valve 106C (shown in FIG. 3). The lower accessory seat 154 may be vertically registered with the intermediate accessory seat 134 (shown in FIG. 5), for example, such that the lower accessory seat 154 underlies the substrate 2 (shown in FIG. 1) when the substrate 2 is supported within the lower chamber 162 (shown in FIG. 4) of the load lock body 102 (shown in FIG. 2). As will be appreciated by those of skill in the art in view of the present disclosure, lateral alignment of the lower accessory seat 154 with either (of both) the third front-end gate valve 104C and the third back-end gate valve 106C may simplify transfer of substrates into and out of the lower chamber 162 of the load lock body 102. As will also be appreciated by those of skill in the art in view of the present disclosure, registration of the lower accessory seat 154 with the intermediate accessory seat 134 may facilitate substrate heating and/or substrate cooling in examples of the load lock arrangement 100 (shown in FIG. 1) when substrate heating and/or substrate within the lower chamber 162 of the load lock body 102 is required.

In certain examples the lower accessory seat 154 may be a first lower accessory seat 154A and the lower plate member 132 may define a second lower accessory seat 154B. The second lower accessory seat 154B may be similar to the first lower accessory seat 154A and may additionally be laterally offset from the first lower accessory seat 154A, for example, on a side of the transfer axis 36 (shown in FIG. 1) opposite that of the first lower accessory seat 154A. The second lower accessory seat 154B may be laterally aligned to the fourth front-end gate valve 104D (shown in FIG. 2). The second lower accessory seat 154B may be laterally aligned to the fourth back-end gate valve 106D (shown in FIG. 2). The second lower accessory seat 154B may be vertically registered with the second intermediate accessory seat 134B (shown in FIG. 5), for example, such that the second lower accessory seat 154B underlies the substrate 2 (shown in FIG. 1) when supported within the lower chamber 162 (shown in FIG. 4) of the load lock body 102 (shown in FIG. 2). As will be appreciated by those of skill in the art in view of the present disclosure, lateral alignment of the second lower accessory seat 154B with either (or both) the fourth front-end gate valve 104D and the fourth back-end gate valve 106D may simplify transfer of substrates into and out of the lower chamber 162 of the load lock body 102. As will also be appreciated by those of skill in the art in view of the present disclosure, registration of the second lower accessory seat 154B with the second intermediate accessory seat 134B may facilitate heating and/or cooling of the substrate 2 in examples of the load lock arrangement 100 (shown in FIG. 1) where substrate heating and/or substrate cooling within the lower chamber 162 is required.

In examples where neither substrate heating nor substrate cooling is required within the lower chamber 162 (shown in FIG. 4), the lower accessory seat blanking plate 124 may be fixed to the lower accessory seat 154. The lower accessory seat blanking plate 124 may be similar to the upper accessory seat blanking plate 114 (shown in FIG. 7) and additionally fluidly separate the lower chamber 162 of the load lock body 102 (shown in FIG. 2) from an external environment 62 (shown in FIG. 1), the upper chamber 160 of the load lock body 102 thereby fluidly isolated from the external environment 62. In accordance with certain examples, the lower accessory seat blanking plate 124 may be a first lower accessory seat blanking plate 124B and the load lock arrangement 100 (shown in FIG. 1) may include a second lower accessory seat blanking plate 124B. The second lower accessory seat blanking plate 124B may be similar to the first lower accessory seat blanking plate 124A, may additionally be fixed to the lower plate member 132 at the second upper accessory seat 140B, and further fluidly separate the lower chamber 162 of the load lock body 102 from the external environment 62 (shown in FIG. 1) outside of the load lock arrangement 100.

As shown in FIG. 10, the lower heater 122 may be fixed to the lower accessory seat 154 in examples where the load lock arrangement 100 (shown in FIG. 1) requires substrate heating within the lower chamber 162 of the load lock body 102 (shown in FIG. 2). In this respect the lower heater 122 may similar to the upper heater 112 (shown in FIG. 8) and configured to radiantly heat a substrate, e.g., the substrate 2 (shown FIG. 2), supported within the lower chamber 162 of the load lock body 102 (shown in FIG. 2). In further respect, it is also contemplated that that the lower heater 122 may include a resistive heater element and/or a fluid heat source to heat the substrate 2, for example, using conduction and/or convection, and remain within the scope of the present disclosure. As will be appreciated by those of skill in the art in view of the present disclosure, employment of resistive and/or fluid heating devices enable heating the substrate 2 during intervals when the lower chamber 162 is not evacuated, for example, during venting and/or evacuation of the lower chamber 162 where transient pressure conditions may exist within the lower chamber 162 of the load lock body 102.

In certain examples, the lower heater 122 may be a first lower heater 122A and the load lock arrangement 100 (shown in FIG. 1) may include a second lower heater 122B. The second lower heater 122B may be similar to the first lower heater 122A and additionally fixed to the lower plate member 132 at the second lower accessory seat 154B to heat a substrate, e.g., the substrate 2 (shown in FIG. 1), while supported within the lower chamber 162 (shown in FIG. 4) of the load lock body 102 (shown in FIG. 2). In accordance with certain examples, the second lower accessory seat 154B (and the second lower heater 122B) may be laterally separated from the first lower accessory seat 154A (and the first lower heater seat 122A) by a lower evacuation/venting port 166. The lower evacuation/venting port 166 may be similar to the upper evacuation/venting port 164 (shown in FIG. 7) may be fluidly coupled to the evacuation/venting source 20 (shown in FIG. 1) for evacuation/venting of the lower chamber 162 to provide evacuation/venting of the lower chamber 162 independently of the upper chamber 160 (shown in FIG. 4) of the load lock body 102, also providing scheduling flexibility to the semiconductor processing system 10 (shown in FIG. 1).

As shown in FIG. 11, the lower chill plate 120 may be fixed to the lower accessory seat 154 in examples where the load lock arrangement 100 (shown in FIG. 1) requires substrate cooling within the lower chamber 162 of the load lock body 102 (shown in FIG. 2). In this respect the lower chill plate 120 may similar to the lower chill plate 120 (shown in FIG. 6) and configured to cool a substrate, e.g., the substrate 2 (shown FIG. 2), supported within the lower chamber 162 of the load lock body 102. Cooling may be accomplished, for example, by convection by introducing a fluid between the substrate 2 and an upper surface of the lower chill plate 120. As will be appreciated by those of skill in the art in view of the present disclosure, employment of fluid coolant for convective cooling enables cooling of the substrate 2 during intervals when the lower chamber 162 is under evacuation as well as when vented or under transient pressure conditions, increasing the rate at which the substrate 2 may be cooled and thereby throughput of the semiconductor processing system 10 (shown in FIG. 1).

In certain examples the lower chill plate 120 may be a first lower chill plate 120A and the load lock arrangement 100 (shown in FIG. 1) may include a second lower chill plate 120B. The second lower chill plate 120B may be similar to the first lower chill plate 120A and additionally fixed to the lower plate member 132 at the second lower accessory seat 154B to cool a substrate, e.g., the substrate 2 (shown in FIG. 1), while supported within the lower chamber 162 (shown in FIG. 4) above the second lower accessory seat 154B. In accordance with certain examples, the second lower accessory seat 154B (and the second lower chill plate 120B) may be laterally separated from the first lower accessory seat 154A (and the first lower chill plate 120A) by the lower evacuation/venting port 166 to provide symmetrical cooling of substrates supported above the first lower chill plate 120A and the second lower chill plate 120B using fluid issued from the first lower chill plate 120A and the second lower chill plate 120B.

With continuing reference to FIG. 9, the lower set plate actuator seat 182 may be similar to the upper set plate actuator seat 174 (shown in FIG. 7) and may additionally be configured for fixation thereon a lower actuator seat blanking plate 190 and a lower set plate actuator 180 (shown in FIG. 11). The lower actuator seat blanking plate 190 may be similar to the upper actuator seat blanking plate 188 (shown in FIG. 8) and additionally configured for fixation at the lower set plate actuator seat 182 for fluid separation of the lower chamber 162 from the external environment 62 (shown in FIG. 1). The lower set plate actuator 180 may be similar to the upper set plate actuator 172 (shown in FIG. 7), may additionally be operatively connected to the lower set plate 110 (shown in FIG. 4), and may be further configured to move the lower set plate 110 between a first lower set plate position 184 (shown in FIG. 15) and a second lower set plate position 186 (shown in FIG. 15).

In certain examples the lower set plate actuator seat 182 may be a first lower set plate actuator seat 182A and the lower plate member 132 may define a second lower set plate actuator seat 182B and a third lower set plate actuator seat 182C. The second lower set plate actuator seat 182B and the third lower set plate actuator seat 182C may be similar to the first lower set plate actuator seat 182A. The second lower set plate actuator seat 182B may be configured for alternative fixation thereto a second lower set plate actuator seat blanking plate 180B and a second lower set plate actuator 180B (shown in FIG. 11). The third lower set plate actuator seat 182C may be configured for alternative fixation thereto a third lower actuator seat blanking plate 190C and a third lower set plate actuator 180C. In examples including the lower set plate actuator seat blanking plates 190A-190C the lower set plate actuator seat blanking plates 190A-190C may fluidly separate the lower chamber 162 (shown in FIG. 4) from the external environment 62 (shown in FIG. 1). In examples including the second lower set plate actuator 180B (shown in FIG. 11) and the third lower set plate actuator 180C (shown in FIG. 11), the second lower set plate actuator 190B and the third lower set plate actuator 180C may cooperate with the first lower set plate actuator 180A to move the lower set plate 110 (shown in FIG. 4) between the first lower set plate position 184 (shown in FIG. 15) and the second lower set plate position 186 (shown in FIG. 15), for example, for paired substrate heating and/or cooling within the lower chamber 162 of the load lock body 102 (shown in FIG. 2).

With reference to FIGS. 12-15, section view of examples of the load lock arrangement 100 are shown. Referring to FIG. 12, the load lock arrangement 100 is shown according to an example where neither substrate heating nor substrate cooling are required within either of the upper chamber 160 and the lower chamber 162 of the load lock body 102. In the illustrated example the load lock arrangement includes the load lock body 102, the first upper accessory seat blanking plate 114A, and the second upper accessory seat blanking plate 114B. The load lock arrangement 100 also includes the first intermediate accessory seat blanking plate 118A, the second intermediate accessory seat blanking plate 118B, the first lower accessory seat blanking plate 124A, and the second lower accessory seat blanking plate 124B. The load lock arrangement 100 further includes the upper actuator seat blanking plates 188A-188C and the lower set plate actuator seat blanking plates 190A-190C. It is also contemplated that the load lock arrangement 100 include the upper set plates 108A-108D and the lower set plates 110A-110D. As will be appreciated by those of skill in the art in view of present disclosure the load lock arrangement 100 may include other elements and/or omit certain illustrated elements and remain within the scope of the present disclosure.

The first upper accessory seat blanking plate 114A is fixed to the first upper accessory seat 140A and the second upper accessory seat blanking plate 114B is fixed to the second upper accessory seat 140B. The first intermediate accessory seat blanking plate 118A is fixed to the first intermediate accessory seat 134A and the second intermediate accessory seat blanking plate 118B is fixed to the second intermediate accessory seat 134B. The first lower accessory seat blanking plate 124A is fixed to the first lower accessory seat 154A and the second lower accessory seat blanking plate 124B is fixed to the second lower accessory seat 154B. It is contemplated that the upper actuator seat blanking plates 188A-188C be fixed to the upper set plate actuator seats 174A-174C, and that lower set plate actuator seat blanking plates 190A-190C be fixed to the lower set plate actuator seats 182A-182C. It is also contemplated that the upper set plates 108A-108D further be arranged within the upper chamber 160 of the load lock body 102 and fixed therein relative to the load lock body 102, and that the lower set plates 110A-110D further be arranged within the lower chamber 162 of the load lock body 102 and fixed within the lower chamber 162 relative to the load lock body 102.

Advantageously, fixation of the upper accessory seat blanking plates 114A-114B to the upper accessory seats 140A-140B enable conversion of the illustrated example of the load lock arrangement 100 to an arrangement where substrate heating may be provided within the upper chamber 160 without customizing the load lock body 102, limiting cost of the illustrated example of the load lock arrangement 100. To additional advantage, fixation of the intermediate accessory seat blanking plates 118A-118B to the intermediate accessory seat blanking plates 118A-118B and fixation of the upper actuator seat blanking plates 188A-188C to the upper set plate actuator seats 174A-174C also enables conversion of the illustrated example of the load lock arrangement 100 to an arrangement where substrate cooling may be provided within the upper chamber 160 without customization of the load lock body 102, also limiting cost of the illustrated example of the load lock arrangement 100. To further advantage, fixation of the lower accessory seat blanking plates 124A-124B to the lower accessory seats 154A-154B and fixation of the lower set plate actuator seat blanking plates 190A-190C to the lower set plate actuator seats 182A-182C further enables conversion of the illustrated example of the load lock arrangement 100 to arrangements where substrate heating and/or substrate cooling may be provided in the lower chamber 162 of the load lock arrangement 100, further limiting cost of the illustrated example of the load lock arrangement 100.

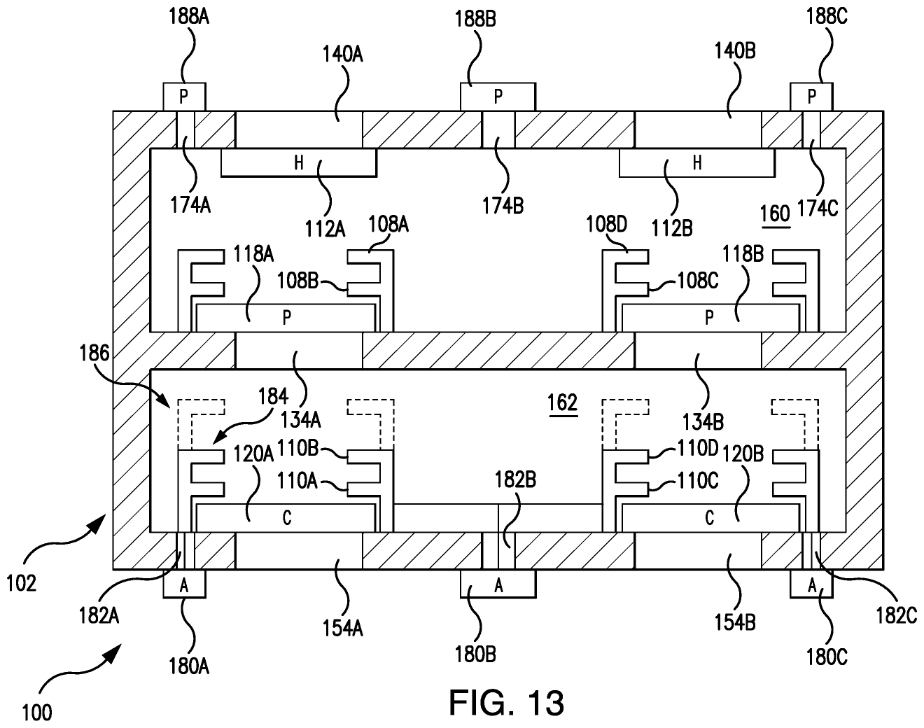

Referring to FIG. 13, the load lock arrangement 100 is shown according to an example where substrate heating and substrate cooling are required within the upper chamber 160 and the lower chamber 162 of the load lock body 102, respectively. In the illustrated example the load lock arrangement 100 includes the load lock body 102, the first upper heater 112A, and the second upper heater 112B. The load lock arrangement 100 also includes the first intermediate accessory seat blanking plate 118A, the second intermediate accessory seat blanking plate 118B, the first lower chill plate 120A, and the second lower chill plate 120B. The load lock arrangement 100 further includes the upper actuator seat blanking plates 188A-188C and the lower set plate actuators 180A-180C. It is also contemplated that, in the illustrated example, the load lock arrangement 100 include the upper set plates 108A-108D and the lower set plates 110A-110D. As will be appreciated by those of skill in the art in view of present disclosure the load lock arrangement 100 may include other elements and/or omit certain illustrated elements and remain within the scope of the present disclosure.

The first upper heater 112A is fixed to the first upper accessory seat 140A and the second upper heater 112B is fixed to the second upper accessory seat 140B to provide substrate heating within the upper chamber 160 of load lock body 102. The first intermediate accessory seat blanking plate 118A is fixed to the first intermediate accessory seat 134A and the second intermediate accessory seat blanking plate 118B is fixed to the second intermediate accessory seat 134B to fluidly separate the upper chamber 160 from the lower chamber 162. The upper set plates 108A-108D arranged within the upper chamber 160 and fixed relative to the load lock body 102 to support a substrate (or substrates) within the upper chamber 160, e.g., during heating of the substrate (or substrates). The first lower chill plate 120A is fixed to the first lower accessory seat 154A and the second lower chill plate 120B is fixed to the second lower accessory seat 154B, the upper actuator seat blanking plates 188A-188C are fixed to the upper set plate actuator seats 174A-174C, and the lower set plate actuators 180A-180C are fixed to the lower set plate actuator seats 182A-182C to move the lower set plates 110A-110C between the first lower set plate position 184, wherein a substrate (or substrates) supported therein are proximate the first lower chill plate 120A and the second lower chill plate 120B, and the second lower set plate position 186, wherein a substrate (or substrates) supported therein are distal from the first lower chill plate 120A and the second lower chill plate 120B according to cooperation of the lower set plate actuators 180A-180C.

Advantageously, fixation of the upper accessory seat blanking plates 114A-114B to the upper accessory seats 140A-140B enable conversion of the illustrated example of the load lock arrangement 100 to an arrangement where substrate heating may be provided within the upper chamber 160 without customizing the load lock body 102, limiting cost of the illustrated example of the load lock arrangement 100. To additional advantage, fixation of the intermediate accessory seat blanking plates 118A-118B to the intermediate accessory seat blanking plates 118A-118B and fixation of the upper actuator seat blanking plates 188A-188C to upper set plate actuator seats 174A-174C also enables conversion of the illustrated example of the load lock arrangement 100 to an arrangement where substrate cooling may be provided within the upper chamber 160 without customization of the load lock body 102, also limiting cost of the illustrated example of the load lock arrangement 100. To further advantage, fixation of the lower chill plates 120A-120B to the lower accessory seats 154A-154B and fixation of the lower set plate actuators 180A-180C to the lower set plate actuator seats 182A-182C further enables conversion of the illustrated example of the load lock arrangement 100 to arrangements where substrate heating may be required in the upper chamber 160 of the load lock body 102 and/or where substrate cooling may not be required within the lower chamber 162 of the load lock body 102, further limiting cost of the illustrated example of the load lock arrangement 100.

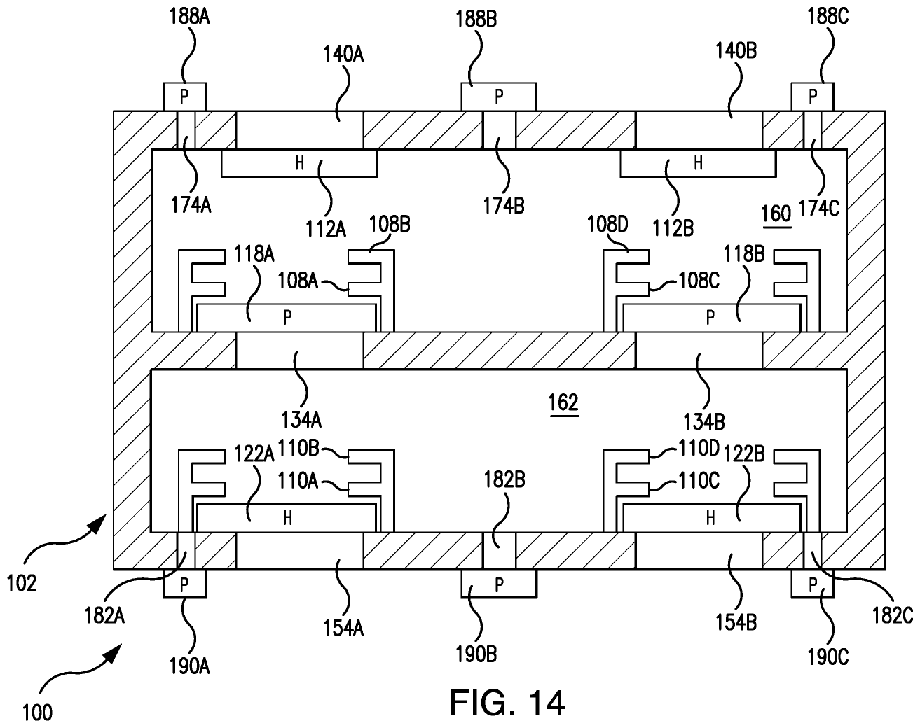

Referring to FIG. 14, the load lock arrangement 100 is shown according to an example where substrate heating is required within both the upper chamber 160 and the lower chamber 162 of the load lock body 102. In the illustrated example the load lock arrangement 100 includes the load lock body 102, the first upper heater 112A, and the second upper heater 112B. The load lock arrangement 100 also includes the first intermediate accessory seat blanking plate 118A, the second intermediate accessory seat blanking plate 118B, the first lower heater 122A, and the second lower heater 122B. The load lock arrangement 100 further includes the upper actuator seat blanking plates 188A-188C and the lower set plate actuator seat blanking plates 190A-190C. It is also contemplated that, in the illustrated example, the load lock arrangement 100 include the upper set plates 108A-108D and the lower set plates 110A-110D. As will be appreciated by those of skill in the art in view of present disclosure the load lock arrangement 100 may include other elements and/or omit certain illustrated elements and remain within the scope of the present disclosure.

The first upper heater 112A is fixed to the first upper accessory seat 140A and the second upper heater 112B is fixed to the second upper accessory seat 140B to provide substrate heating within the upper chamber 160 of load lock body 102. The first intermediate accessory seat blanking plate 118A is fixed to the first intermediate accessory seat 134A and the second intermediate accessory seat blanking plate 118B is fixed to the second intermediate accessory seat 134B to fluidly isolate the upper chamber 160 from the lower chamber 162, and the upper set plates 108A-108D arranged within the upper chamber 160 and fixed relative to the load lock body 102 to support a substrate (or substrates) within the upper chamber 160 (e.g., during substrate heating). The first lower heater 122A is fixed to the first lower accessory seat 154A and the second lower heater 122B is fixed to the second lower accessory seat 154B to heat a substrate (or substrates) supported by the lower set plates 110A-110D, the upper actuator seat blanking plates 188A-188C are fixed to the upper set plate actuator seats 174A-174C to fluidly separate the upper chamber 160 from the external environment 62 (shown in FIG. 1), and the lower set plate actuator seat blanking plates 190A-190C are fixed to the lower set plate actuator seats 182A-182C to fluidly separate the lower chamber 162 from the external environment 62.

Advantageously, fixation of the upper heaters 112A-112B to the upper accessory seats 140A-140B enables conversion of the illustrated example of the load lock arrangement 100 to an arrangement where substrate heating is not required within the upper chamber 160 without customizing the load lock body 102, limiting cost of the illustrated example of the load lock arrangement 100. To additional advantage, fixation of the intermediate accessory seat blanking plates 118A-118B to the intermediate accessory seat blanking plates 118A-118B and fixation of the upper actuator seat blanking plates 188A-188C to upper set plate actuator seats 174A-174C enables conversion of the illustrated example of the load lock arrangement 100 to an arrangement where substrate cooling may be provided within the upper chamber 160 also without requiring customization of the load lock body 102, further limiting cost of the illustrated example of the load lock arrangement 100. To additional advantage, fixation of the lower heaters 122A-122B to the lower accessory seats 154A-154B and fixation of the lower set plate actuator seat blanking plates 190A-190C to the lower set plate actuator seats 182A-182C enables conversion of the illustrated example of the load lock arrangement 100 to arrangements where substrate heating is not required in the upper chamber 160 of the load lock body 102 and/or where substrate cooling is required within the lower chamber 162 of the load lock body 102, additionally limiting cost of the illustrated example of the load lock arrangement 100.

Referring to FIG. 15, the load lock arrangement 100 is shown according to an example where substrate cooling is required within both the upper chamber 160 and the lower chamber 162 of the load lock body 102. In the illustrated example the load lock arrangement 100 includes the load lock body 102, the first upper accessory seat blanking plate 114A, and the second upper accessory seat blanking plate 114B. The load lock arrangement 100 also includes the first upper chill plate 116A, the second upper chill plate 116B, the first lower chill plate 120A, and the second lower chill plate 120B. The load lock arrangement 100 further includes the upper set plate actuators 172A-172C and the lower set plate actuators 180A-180C. It is also contemplated that, in the illustrated example, the load lock arrangement 100 include the upper set plates 108A-108D and the lower set plates 110A-110D. As will be appreciated by those of skill in the art in view of present disclosure the load lock arrangement 100 may include other elements and/or omit certain illustrated elements and remain within the scope of the present disclosure.

The first upper accessory seat blanking plate 114A is fixed to the first upper accessory seat 140A and the second upper accessory seat blanking plate 114B is fixed to the second upper accessory seat 140B to fluidly isolate the upper chamber 160 from the external environment 62 outside the load lock body 102. The first upper chill plate 116A is fixed to the first intermediate accessory seat 134A and the second upper chill plate 116B is fixed to the second intermediate accessory seat 134B. The upper set plates 108A-108D are arranged within the upper chamber 160 and fixed relative to the load lock body 102 and the upper set plate actuators 172A-172D are fixed to the upper set plate actuator seats 174A-174C to cooperatively move the upper set plates 108A-108D between the first upper set plate position 176 and the second upper set plate position 178. When in the first upper set plate position 176 a substrate (or substrates) supported by the upper set plates 108 are proximate the lower chill plates 116A-116B, increasing the rate at which the substrate (or substrates) are cooled within the upper chamber 160. As will be appreciated by those of skill in the art in view of the present disclosure, this may increase throughput of the semiconductor processing system 10 (show in FIG. 1).

The first lower chill plate 120A is fixed to the first lower accessory seat 154A and the second lower chill plate 120B is fixed to the second lower accessory seat 154B and the lower set plate actuators 180A-180C are fixed to the lower set plate actuator seats 182A-182C. The lower set plate actuators 180A-180C are further configured to move the lower set plates 110A-110C between the first lower set plate position 184, wherein a substrate (or substrates) supported therein are proximate the first lower chill plate 120A and the second lower chill plate 120B, and the second lower set plate position 186, wherein a substrate (or substrates) supported therein are distal from the first lower chill plate 120A and the second lower chill plate 120B according to cooperation of the lower set plate actuators 180A-180C. As will also be appreciated by those of skill in the art in view of the present disclosure, this may increase throughput of the semiconductor processing system 10 (show in FIG. 1). The upper chill plates 116A-116B may further fluidly separate the upper chamber 160 from the lower chamber 162, the upper chamber 160 thereby being fluidly isolated from the lower chamber 162, and the lower chill plates 120A-120B may further fluidly separate the lower chamber 162 from the external environment 62 (shown in FIG. 1) outside of the load lock body 102.

Advantageously, fixation of the upper accessory seat blanking plates 114A-114B to the upper accessory seats 140A-140B enables conversion of the illustrated example of the load lock arrangement 100 to an arrangement where substrate heating may be provided within the upper chamber 160 without customizing the load lock body 102, limiting cost of the illustrated example of the load lock arrangement 100. To additional advantage, fixation of the upper chill plates 116A-116B to the intermediate accessory seats 134A-134B enables conversion of the illustrated example of the load lock arrangement 100 to an arrangement where substrate cooling may be removed and/or substrate heating provided within the upper chamber 160 without customization of the load lock body 102, also limiting cost of the illustrated example of the load lock arrangement 100. To further advantage, fixation of the lower chill plates 120A-120B to the lower accessory seats 154A-154B and fixation of the lower set plate actuators 180A-180C to the lower set plate actuator seats 182A-182C further enables conversion of the illustrated example of the load lock arrangement 100 to arrangements where substrate cooling may be removed and/or substrate heating provided within the lower chamber 162 of the load lock body 102, further limiting cost of the illustrated example of the load lock arrangement 100.

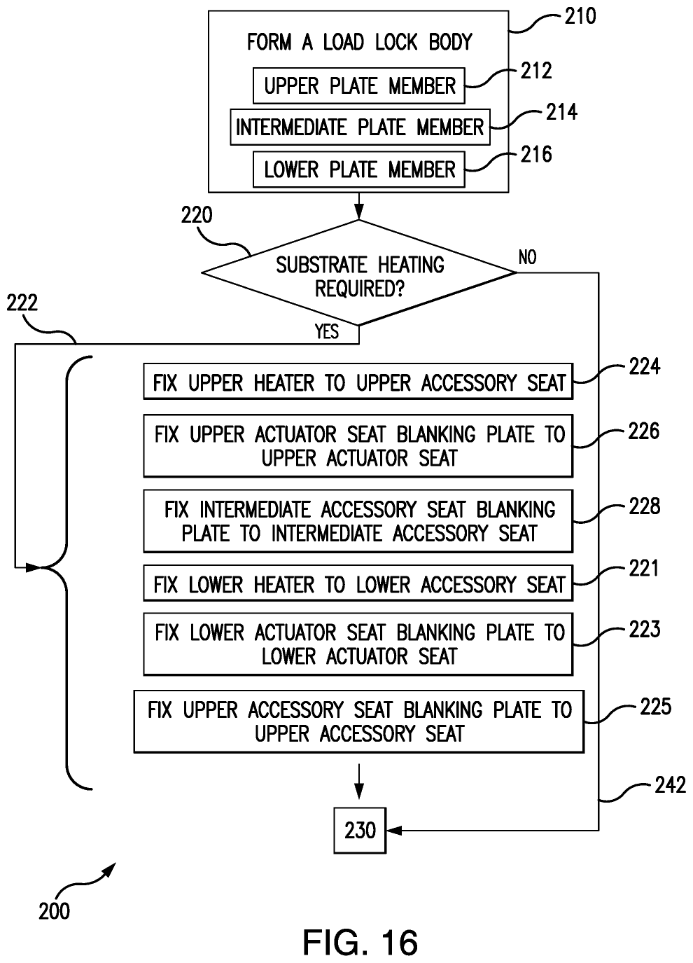

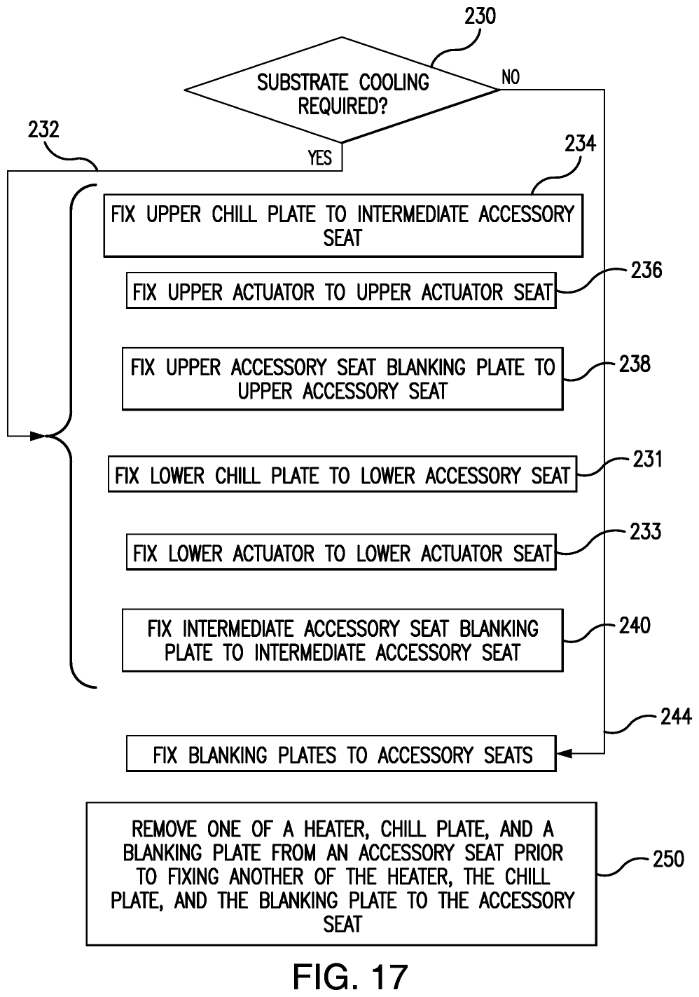

With reference to FIGS. 16 and 17, a method 200 of making a load lock arrangement for a semiconductor processing system, e.g., the load lock arrangement 100 (shown in FIG. 1), is shown. The method 200 includes forming a load lock body, e.g., the load lock body 102 (shown in FIG. 2), as shown with box 210. The method 200 also includes determining whether substrate heating is required within an upper chamber of the load lock body, e.g., the upper chamber 160 (shown in FIG. 4) of the load lock body, as shown with box 220. The method 200 further includes determining whether substrate cooling is required within upper chamber of the load lock body, as shown with box 230. As will be appreciated by those of skill in the art in view of the present disclosure, the method 200 may include additional operations or omit certain operations shown and described herein and remain within the scope of the present disclosure.

Forming 210 the load lock body may include defining one or more upper accessory seat in an upper plate member and one or more upper set plate actuator seat in an upper plate member of the load lock body, e.g., the upper accessory seat 140 (shown in FIG. 7) and the upper set plate actuator seat 174 (shown in FIG. 7) in the upper plate member 130 (shown in FIG. 7), as shown with box 212. Forming 210 the load lock body may also include defining an intermediate accessory seat within an intermediate plate member, e.g., the intermediate accessory seat 134 (shown in FIG. 5) within the intermediate plate member 128 (shown in FIG. 5), as shown with box 214. Forming 210 the load lock body may further include defining one or more lower accessory seat and one or more lower set plate actuator seat within a lower plate member of the load lock body, e.g., the lower accessory seat 154 (shown in FIG. 9) and the lower set plate actuator seat 182 (shown in FIG. 9) of the lower plate member 132 (shown in FIG. 9), as shown with box 216.

When substrate heating is required an upper heater may be fixed to the upper accessory seat defined in the upper plate member, e.g., the upper heater 112 (shown in FIG. 8) fixed to the upper accessory seat, as shown with arrow 222 and box 224. An upper set plate actuator blanking plate may be fixed to the upper set plate actuator seat defined by the upper plate member when substrate heating is required, e.g., the upper set plate actuator blanking plate 188 (shown in FIG. 8), as shown with arrow 222 and box 226. An intermediate accessory seat blanking plate may be fixed to the intermediate accessory seat defined by the upper plate member when substrate heating is required, e.g., the intermediate accessory seat blanking plate 118 (shown in FIG. 5) fixed to the intermediate accessory seat, as shown with arrow 222 and box 228. A lower heater may be fixed to the lower heater seat defined by the lower plate member when substrate heating is required, e.g., the lower heater 122 (shown in FIG. 10), as shown with arrow 222 and box 221. A lower set plate actuator blanking plate may be fixed to the lower set plate actuator seat defined by the lower plate member when substrate heating is required, e.g. the lower set plate actuator seat blanking plate 190 (shown in FIG. 9), as shown with arrow 222 and box 223. It is also contemplated that an upper accessory seat blanking plate may be fixed to the upper accessory seat defined by the upper plate member when substrate heating is required, e.g., the upper accessory seat blanking plate 124 (shown in FIG. 9), as further shown with arrow 222 and box 225. Determination that substrate cooling is required may be when the need tool to heat a substrate to a desired material layer deposition temperature renders a process module a throughput constraint, e.g., when the process module 12 (shown in FIG. 1) is employed to deposit material layers at a relatively high temperature using an ALD technique.

When substrate cooling is required an upper chill plate may be fixed to the intermediate accessory seat defined in the intermediate plate member, e.g., the upper chill plate 116 (shown in FIG. 6) fixed to the intermediate accessory seat, as shown with arrow 232 and box 234. An upper set plate actuator may be fixed to the upper set plate actuator seat defined by the upper plate member when substrate cooling is required in the load lock arrangement, e.g., the upper set plate actuator 172 (shown in FIG. 7), as shown with arrow 232 and box 236. An upper accessory seat blanking plate may be fixed to the upper accessory seat defined by the upper plate member when substrate heating is required in the load lock arrangement, e.g., the upper accessory seat blanking plate 114 (shown in FIG. 7) fixed to the upper accessory seat, as shown with arrow 232 and box 238. A lower chill plate may be fixed to the lower heater seat defined by the lower plate member when substrate cooling is required within the load lock arrangement, e.g., the chill plate 120 (shown in FIG. 11), as shown with arrow 232 and box 231. A lower set plate actuator may be fixed to the lower set plate actuator seat defined by the lower plate member when substrate cooling is required within the load lock arrangement, e.g. the lower set plate actuator 180 (shown in FIG. 11), as shown with arrow 232 and box 233. It is also contemplated that an intermediate accessory seat blanking plate may be fixed to the intermediate accessory seat defined by the intermediate plate member when substrate cooling is required in the load lock arrangement, e.g., the intermediate accessory seat blanking plate 118 (shown in FIG. 5), as further shown with arrow 232 and box 235. Determination that substrate cooling is required may be when the need tool to cool a substrate following material layer deposition renders a process module a throughput constraint, e.g., when the process module 12 (shown in FIG. 1) is employed to deposit material layers at a relatively high temperature using an ALD technique.

When substrate heating and substrate cooling are not required, blanking plates may be fixed to accessory seats in the load lock body, as shown with box 240. For example, when substrate heating is not required, the upper accessory plate may be fixed to the upper accessory seat and the lower accessory seat blanking plate fixed to the lower accessory seat, as shown with arrow 242 and arrow 244. The upper set plate actuator seat blanking plate may be fixed to the upper actuator set plate actuator seat when substrate heating and substrate cooling are not required, as also show with arrow 242 and arrow 244. The lower set plate actuator seat blanking plate may be fixed to the lower set plate actuator set when substrate heating and substrate cooling are not required, as further shown with arrow 242 and arrow 244. As shown with box 250, it is also contemplated that one or more of the aforementioned blanking plates may be removed from an accessory seat when it is determined that substrate heating and/or substrate cooling is required, for example, when conversion of a process module to a higher temperature deposition process renders the process module a throughput constraint to the semiconductor processing system including the load lock arrangement.

With reference to FIG. 18, the material layer deposition method 300 is shown. A shown with box 310, the method 300 includes transferring a substrate from an EFEM into a load lock arrangement, e.g., the substrate 2 (shown in FIG. 1) from the EFEM 16 (shown in FIG. 1) into the load lock arrangement 100 (shown in FIG. 1). In certain examples the substrate may be heated while supported within the load lock arrangement, as shown with box 312. In accordance with certain examples, the substrate may be maintained at substantially constant temperature while supported within the load lock arrangement, for example, between insertion into the load lock arrangement by a front-end substrate transfer robot and retrieval of the substrate from the load lock arrangement by a back-end substrate transfer robot, as shown with box 314. The substrate may then be transferred into a process module, e.g., the process module 12 (shown in FIG. 1), and a material layer deposited onto the substrate, e.g., the material layer 4 (shown in FIG. 1), as shown with box 320 and body 330. As shown with box 340, the substrate may thereafter be transferred with the material layer deposited thereon into the load lock arrangement and therefrom into the EFEM, as shown with box 340. In certain examples, the substrate may be cooled within the load lock arrangement, as shown with box 342. It is also contemplated that the substrate may be maintained at substantially constant temperature while supported within the load lock arrangement, e.g., between insertion into the load lock arrangement by the back-end substrate transfer robot and retrieval of the substrate and the material layer deposited thereon from the load lock arrangement by the front-end substrate transfer robot, as shown with box 344.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A load lock arrangement, comprising:
a load lock body having:
an upper plate member defining an upper accessory seat;
an intermediate plate member spaced apart from the upper plate member and defining an intermediate accessory seat; and
a lower plate member separated from the upper plate member by the intermediate plate member and defining a lower accessory seat;
one of an upper heater and an upper accessory seat blanking plate fixed to the upper accessory seat;
one of an upper chill plate and an intermediate accessory seat blanking plate fixed to the intermediate accessory seat; and
one of a lower chill plate, a lower heater, and a lower accessory seat blanking plate fixed to the lower accessory seat.

2. The load lock arrangement of claim 1, wherein the upper accessory seat blanking plate is fixed to the upper accessory seat, wherein the intermediate accessory seat blanking plate is fixed to the intermediate accessory seat, and wherein the lower accessory seat blanking plate is fixed to the lower accessory seat.

3. The load lock arrangement of claim 2, wherein the upper plate member defines an upper actuator seat, and wherein the load lock arrangement further comprises an upper actuator seat blanking plate fixed to the upper actuator seat.

4. The load lock arrangement of claim 2, wherein the lower plate member defines a lower actuator seat, and wherein the load lock arrangement further comprises a lower actuator seat blanking plate fixed to the lower actuator seat.

5. The load lock arrangement of claim 1, wherein the upper heater is fixed to the upper accessory seat, wherein the lower chill plate is fixed to the lower accessory seat, and wherein the intermediate accessory seat blanking plate is fixed to the intermediate accessory seat defined by the intermediate plate member of the load lock body.

6. The load lock arrangement of claim 5, wherein the upper plate member defines an upper actuator seat, and wherein the load lock arrangement further comprises an upper actuator seat blanking plate fixed to the upper actuator seat defined within the upper plate member of the load lock body.

7. The load lock arrangement of claim 5, wherein the lower plate member defines a lower actuator seat and further comprising a lower set plate actuator fixed to the lower set plate actuator seat, and wherein the lower set plate actuator is configured to move a lower set plate between a first lower set plate position and a second lower set plate position relative to the lower plate member.

8. The load lock arrangement of claim 1, further comprising an evacuation/vent source connected to the load lock body for evacuation/venting or purging one or more of an upper chamber and a lower chamber defined within the load lock body.

9. The load lock arrangement of claim 1, wherein the upper heater is fixed to the upper accessory seat, wherein the lower heater is fixed to the lower accessory seat, and wherein the intermediate accessory seat blanking plate is fixed to the intermediate accessory seat.

10. The load lock arrangement of claim 9, wherein the upper plate member defines an upper actuator seat and further comprising an upper actuator seat blanking plate fixed to the upper actuator seat.

11. The load lock arrangement of claim 9, wherein the lower plate member defines a lower actuator seat, and wherein the load lock arrangement further comprises a lower actuator seat blanking plate fixed to the lower actuator seat.

12. The load lock arrangement of claim 1, wherein the upper chill plate is fixed to the intermediate accessory seat, wherein the lower chill plate is fixed to the lower accessory seat, and wherein the upper accessory seat blanking plate is fixed to the upper accessory seat.

13. The load lock arrangement of claim 12, wherein the upper plate member defines an upper actuator seat and further comprising an upper set plate actuator fixed to the upper actuator seat, the upper set plate actuator configured to move an upper set plate between a first upper set plate position and a second upper set plate position relative to the upper plate member.

14. The load lock arrangement of claim 12, wherein the lower plate member defines a lower actuator seat and further comprising a lower set plate actuator fixed to the lower actuator seat, the lower set plate actuator configured to move a lower set plate between a first lower set plate position and a second lower set plate position relative to the lower plate member.

15. The load lock arrangement of claim 1, wherein the load lock body defines an upper chamber bounded by the upper plate member and the intermediate plate member, and further comprising:
a first upper set plate arranged between the upper accessory seat and the intermediate accessory seat; and
a second upper set plate stacked on the first upper set plate and arranged between the first upper set plate and the upper accessory seat.

16. The load lock arrangement of claim 15, wherein the first upper set plate and the second upper set plate are fixed within the upper chamber relative to the upper plate member.

17. The load lock arrangement of claim 15, wherein the second upper set plate is fixed relative to the first upper set plate, and wherein the first upper set plate has a first upper set plate position and a second upper set plate position, the first upper set plate proximate the intermediate accessory seat in the first upper set plate position, the first upper set plate distal from the intermediate accessory seat in the second upper set plate position.

18. The load lock arrangement of claim 1, wherein the load lock body defines a lower chamber bounded by the intermediate plate member and the lower plate member, and further comprising:
a first lower set plate arranged between the intermediate accessory seat and the lower accessory seat; and
a second lower set plate stacked on the first lower set plate and arranged between the first lower set plate and the intermediate accessory seat.

19. The load lock arrangement of claim 18, wherein the first lower set plate and the second lower set plate are fixed within the lower chamber relative to the upper plate member.

20. The load lock arrangement of claim 18, wherein the second lower set plate is fixed relative to the first lower set plate, and wherein the first lower set plate has a first lower set plate position and a second lower set plate position, the first lower set plate proximate the lower accessory seat in the first lower set plate position, the first lower set plate distal from the lower accessory seat in the second lower set plate position.

21. A semiconductor processing system, comprising:
a process module;
a back-end transfer module connected to the process module and housing a back-end substrate transfer robot; and
a load lock arrangement as recited in claim 1 connected to back-end transfer module and coupling the process module to an equipment front-end module housing a front-end substrate transfer robot;
wherein the load lock body defines an upper chamber bounded by the upper plate member and member and the intermediate plate member;
wherein the load lock body defines a lower chamber bounded by the intermediate plate member and the lower plate member; and
wherein the front-end substrate transfer robot and the back-end substrate transfer robot are configured to transfer substrates between the equipment front-end module and the process module through the upper chamber and the lower chamber defined within the load lock body.

22. The semiconductor processing system of claim 21, wherein the upper accessory seat blanking plate is fixed to the upper accessory seat, wherein the intermediate accessory seat blanking plate is fixed to the intermediate accessory seat, wherein the lower accessory seat blanking plate is fixed to the lower accessory seat, the load lock arrangement further comprising:
a first upper set plate arranged between the upper accessory seat and the intermediate accessory seat, the first upper set plate fixed relative to the load lock body; and
a second upper set plate stacked on the first upper set plate and arranged between the first upper set plate and the upper accessory seat, the second upper set plate fixed relative to the first upper set plate.

23. The semiconductor processing system of claim 21, wherein the upper heater is fixed to the upper accessory seat, wherein the lower chill plate is fixed to the lower accessory seat, wherein the intermediate accessory seat blanking plate is fixed to the intermediate accessory seat, the load lock arrangement further comprising:
a first upper set plate arranged between the upper accessory seat and the intermediate accessory seat, the first upper set plate fixed relative to the load lock body; and
a first lower set plate arranged between the lower accessory seat and the intermediate accessory seat, the first lower set plate movable relative to the load lock body between a first lower set plate position and a second lower set plate position.

24. The semiconductor processing system of claim 21, wherein the upper heater is fixed to the upper accessory seat, wherein the lower heater is fixed to the lower accessory seat, wherein the intermediate accessory seat blanking plate is fixed to the intermediate accessory seat, the load lock arrangement further comprising:
a first upper set plate arranged between the upper accessory seat and the intermediate accessory seat, the first upper set plate fixed relative to the load lock body; and
a first lower set plate arranged between the lower accessory seat and the intermediate accessory seat, the first lower set plate fixed relative to the load lock body.

25. The semiconductor processing system of claim 21, wherein the upper chill plate is fixed to the intermediate accessory seat, wherein the lower chill plate is fixed to the lower accessory seat, and wherein the upper accessory seat blanking plate is fixed to the upper accessory seat, the load lock arrangement further comprising:
a first upper set plate arranged between the upper accessory seat and the intermediate accessory seat, the first upper set plate movable relative to the load lock body between a first upper set plate position and a second upper set plate position; and
a first lower set plate arranged between the lower accessory seat and the intermediate accessory seat, the first lower set plate movable relative to the load lock body between a first lower set plate position and a second lower set plate position.

26. A material layer deposition method, comprising:
at a load lock arrangement includes a load lock body having an upper plate member defining an upper accessory seat, an intermediate plate member spaced apart from the upper plate member and defining an intermediate accessory seat, and a lower plate member separated from the upper plate member by the intermediate plate member and defining a lower accessory seat; one of an upper heater and an upper accessory seat blanking plate is fixed to the upper accessory seat;
one of an upper chill plate and an intermediate accessory seat blanking plate fixed to the intermediate accessory seat; and one of a lower chill plate, a lower heater, and a lower accessory seat blanking plate fixed to the lower accessory seat;
transferring a substrate from an equipment front-end module into the load lock body;
transferring the substrate from the load lock body into a process module;
depositing a material layer onto the substrate using the process module;
transferring the substrate to the load lock body;
transferring the substrate from the load lock body to the equipment front-end module; and
wherein the substrate is one of (a) heated, (b) cooled, or (c) retained at a substantially constant temperature while supported within the load lock body.

27. The material layer deposition method of claim 26, wherein transferring the substrate from the equipment front-end module into the load lock body comprises heating the substrate in the load lock body.

28. The material layer deposition method of claim 26, wherein transferring the substrate from the process module into the load lock body comprises cooling the substrate in the load lock body.

29. The material layer deposition method of claim 26, wherein transferring the substrate from the equipment front-end module comprises maintaining the substrate at a substantially constant temperature within the load lock body, and wherein transferring the substrate from the process module comprises maintaining the substrate at a substantially constant temperature.

30. A method of making a load lock arrangement, comprising:
at a load lock arrangement including a load lock body having an upper plate member defining an upper accessory seat, an intermediate plate member spaced apart from the upper plate member and defining an intermediate accessory seat, and a lower plate member separated from the upper plate member by the intermediate plate member and defining a lower accessory seat,
fixing an upper heater to the upper accessory seat when substrate heating is required and fixing an upper accessory seat blanking plate fixed to the upper accessory seat when the substrate heating is not required;
fixing an upper chill plate to the intermediate accessory seat when substrate cooling is required and fixing an intermediate accessory seat blanking plate fixed to the intermediate accessory seat when the substrate cooling is not required; and
fixing a lower chill plate to the lower accessory seat when the substrate cooling is required, fixing a lower heater to the lower accessory seat when the substrate cooling is required, and fixing a lower accessory seat blanking plate to the lower accessory seat when neither the substrate cooling nor the substrate heating is required.
